(19) United States
(12) Patent Application Publication
(10) Pub. No.: US 2024/0403500 A1
(43) Pub. Date: Dec. 5, 2024

(54) REVERSE ENGINEERING SUPPORT APPARATUS

(71) Applicant: Keyence Corporation, Osaka (JP)

(72) Inventor: Kazusa AOKI, Osaka (JP)

(73) Assignee: Keyence Corporation, Osaka (JP)

(21) Appl. No.: 18/635,067

(22) Filed: Apr. 15, 2024

(30) Foreign Application Priority Data
May 31, 2023 (JP) 2023-089481

(51) Int. Cl. G06F 30/12; G06T 19/20

(52) U.S. Cl. CPC G06F 30/12; G06T 19/20; G06T 2219/2012; G06T 2219/2016

(57) ABSTRACT

A reverse engineering support apparatus includes: an extraction unit that extracts a geometric element from mesh data; a reception unit that receives selection of one geometric element from among a plurality of the geometric elements extracted by the extraction unit and selection of a type of a logical operation; a registration unit that registers a plurality of records in which types of logical operations received by the reception unit are associated with the geometric elements, respectively, in a synthesis processing table; a computing unit that executes a logical operation of a geometric element for each of the registered records based on a type of the logical operation associated with each of the records to create a synthetic element; and a display control unit that displays the synthetic element on the display unit.

### CROSS-REFERENCE TO RELATED APPLICATIONS

The present application claims foreign priority based on Japanese Patent Application No. 2023-089481, filed May 31, 2023, the contents of which are incorporated herein by reference.

### BACKGROUND OF THE INVENTION

### 1. Technical Field

The disclosure relates to a reverse engineering support apparatus that supports reverse engineering in which a shape of a real object is acquired, converted into design data, and utilized for manufacturing.

### 2. Description of the Related Art

In recent years, reverse engineering has been used in various fields of manufacturing. For example, the reverse engineering are used for an application in which a shape of an existing product is scanned and converted into CAD data to perform development of a next model and shape analysis on CAD and/or CAE, an application in which a shape of a model or a mock-up in a product design is scanned and converted into CAD data to be reflected in the product design, an application in which a shape of a mating component to be fitted is scanned and converted into CAD data to design a product to be a fitting source, and an application in which a shape of a prototype is scanned and converted into CAD data to be connected to an improved design, and such applications tend to expand.

For example, JP 2018-31746 A discloses a three-dimensional measurement apparatus that measures position information of a plurality of measurement points in a three-dimensional space and generates three-dimensional shape data of a measurement target object.

The three-dimensional measurement apparatus disclosed in JP 2018-31746 A is configured to be capable of extracting a plurality of geometric elements based on the acquired three-dimensional shape data and calculating a distance and an angle between the plurality of extracted geometric elements.

Meanwhile, it is necessary to convert mesh data acquired by measuring a workpiece into CAD data at the time of reverse engineering. However, in general reverse engineering software, it is necessary to perform CAD modeling with the mesh data as a draft, and a proficiency level at the same level as that of CAD software is required.

For example, it is possible to create the CAD data based on the workpiece by creating a basic geometric shape such as a cylinder or a rectangular parallelepiped on the reverse engineering software based on the mesh data acquired by the three-dimensional measurement apparatus or the like, then converting the geometric shape into a solid body, and applying a set operation.

However, it is difficult to handle the general reverse engineering software, and further, it is sometimes not clear as to what shape the result of the set operation will have and what shape has been created as the result of the set operation because the mesh data and the CAD data overlap each other when viewed on a display screen. Further, since it is necessary to designate data to be “combined” with data as a “reference” in the set operation, it is necessary to build a shape while distinguishing these pieces of data, and the difficulty is high. Furthermore, in conventional set operations, only either addition or subtraction can be designated in one operation, and the order of operations and a sign cannot be flexibly changed, and thus, there is also a problem that trial and error is difficult. In short, in the course of converting the mesh data into the CAD data, it is difficult to easily obtain the CAD data which is true to the workpiece and suitable for an intention of a user.

### SUMMARY OF THE INVENTION

The disclosure has been made in view of such points, and an object thereof is to easily obtain CAD data which is true to a workpiece and suitable for an intention of a user in the course of converting mesh data into the CAD data.

In order to achieve the above object, according to one embodiment of the invention, it is possible to assume a reverse engineering support apparatus that converts mesh data, obtained by measuring a shape of a workpiece, into CAD data and outputs the CAD data. The reverse engineering support apparatus includes: a data acquisition unit that acquires the mesh data of the workpiece; an extraction unit that extracts a plurality of geometric elements from the mesh data of the workpiece acquired by the data acquisition unit; a reception unit that receives selection of one geometric element from among the plurality of geometric elements extracted by the extraction unit and receives selection of a type of a logical operation of the one geometric element; a registration unit configured to be capable of registering, in a synthesis processing table, a plurality of records in which types of logical operations received by the reception unit are associated with geometric elements received by the reception unit, respectively; a computing unit that executes a logical operation of a geometric element based on a type of the logical operation associated with each of the records for each of the records, included in the synthesis processing table and registered by the registration unit, to create a synthetic element; and a display control unit that causes a display unit to display the synthetic element created by the computing unit.

According to this configuration, when a user selects one geometric element from among the plurality of geometric elements and further selects a type of a logical operation of the selected one geometric element in a case where the extraction unit extracts the plurality of geometric elements from the mesh data of the workpiece acquired by the data acquisition unit, the selected one geometric element and the type of the logical operation are received by the reception unit. Examples of the selectable logical operation type include addition, subtraction, multiplication, and the like.

The selected one geometric element and logical operation type are associated with each other to constitute a record, and are registered by the registration unit. For example, when the user selects a first geometric element and a first logical operation type, the first geometric element and the first logical operation type are associated with each other to constitute a first record. Further, when the user selects a second geometric element and a second logical operation type, the second geometric element and the second logical operation type are associated with each other to constitute a second record. When the first and second records are configured in this manner, the first and second records are registered in the synthesis processing table. For each of the first and second records registered by the registration unit, the computing unit executes a logical operation of a geometric element based on a type of the logical operation associated with each of the records to create a synthetic element, and the synthetic element created by the computing unit is displayed on the display unit. Thus, the user can easily confirm, on the display unit, what shape a result of a set operation will have and what shape has been created as the result of the set operation only by selecting the geometric element and selecting the type of the logical operation. Of course, a third record, a fourth record, and the like may be registered.

Further, since it is sufficient for the user to select the first geometric element and the first logical operation type and the second geometric element and the second logical operation type, it is not necessary to distinguish between data as a “reference” and data to be “combined”, and the difficulty in creating CAD data is lowered. Furthermore, since any logical operation type can be selected by the user, trial and error at the time of creating CAD data can be easily performed, and conversion into CAD data true to the workpiece and suitable for an intention of the user can be performed.

The reception unit can additionally receive selection of one geometric element and selection of a type of a logical operation of the one geometric element. In this case, the registration unit adds, to the synthesis processing table, a record in which the one additionally received geometric element is associated with the type of logical operation of the one geometric element, the computing unit may execute the logical operation of the one geometric element and the synthetic element based on the record added to the synthesis processing table to update the synthetic element, and the display control unit may cause the display unit to display the synthetic element updated by the computing unit.

According to this configuration, the synthetic element is updated every time the geometric element is added, and the updated synthetic element is displayed on the display unit. Thus, it is easy to confirm the validity of created CAD data, and it is easy to make the CAD data suitable for the intention of the user by repeating trial and error.

The display control unit can display the mesh data, the synthetic element, and synthesis candidates in a form that can be distinguished by the user by causing the display unit to display the synthesis screen including a mesh display area in which the mesh data acquired by the data acquisition unit is displayed, a synthetic element display area in which the synthetic element computed by the computing unit is displayed, and a candidate display area in which the plurality of geometric elements extracted by the extraction unit are displayed as the synthesis candidates. Then, since the user can select one geometric element to be used for a logical operation from among the plurality of geometric elements displayed in the candidate display area, the selection operation can be easily performed.

The synthesis screen may further include a type selection area for selecting a logical operation type. Since the type selection area is provided with an icon for designating the logical operation type of one geometric element received by the reception unit, the user can easily designate addition and subtraction which are frequently designated.

The reception unit may be configured to be capable of receiving a change in the order of the plurality of geometric elements displayed in the selected element display area. In this case, when the reception unit receives the change in the order of the plurality of geometric elements, the computing unit can execute logical operations of the geometric elements displayed in the selected element display area based on types of the logical operations associated with the geometric elements, respectively, in the displayed order to update the synthetic element, and the display control unit can cause the display unit to display the synthetic element updated by the computing unit.

As described above, when the user selects the geometric elements and the logical operation types, these can be associated and registered as the plurality of records, and the synthetic element computed for each of the plurality of registered records can be displayed on the display unit. Thus, it is possible to easily obtain the CAD data which is true to the workpiece and suitable for the intention of the user in the course of converting the mesh data into the CAD data.

### BRIEF DESCRIPTION OF THE DRAWINGS

FIG. 1 is a diagram illustrating an overall configuration of a reverse engineering support apparatus according to an embodiment of the invention;

FIG. 2 is a block diagram of the reverse engineering support apparatus;

FIG. 3 is a side view of a measurement unit and a pedestal;

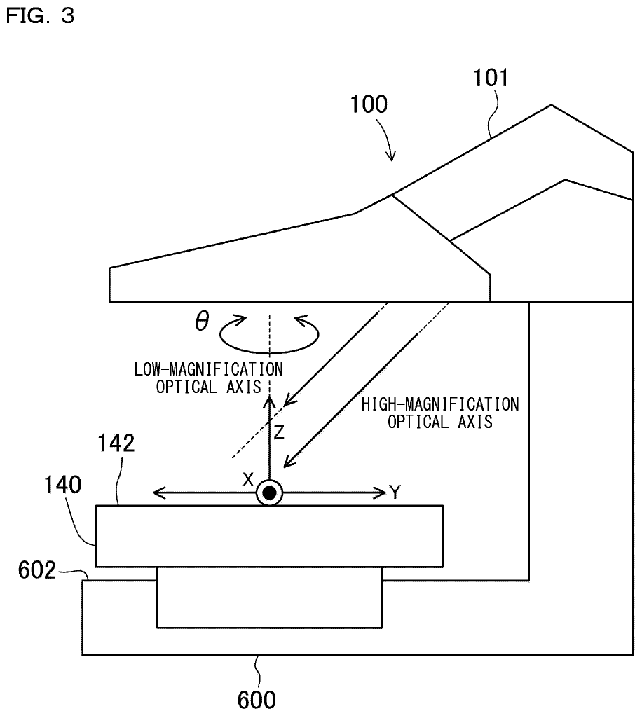

FIG. 4 is a block diagram of the measurement unit;

FIG. 5 is a diagram illustrating configuration examples of modules;

FIG. 6 is a flowchart illustrating an example of an operation of a conversion module;

FIG. 7 is a view illustrating an example of an element setting screen;

FIG. 8 is a view illustrating an example of an element setting screen in a case where a plurality of geometric elements are extracted;

FIG. 9 is a view illustrating an example of CAD data in which a surface slightly remains;

FIG. 10 is a flowchart illustrating an example of an element scaling process on a cylinder or a cone;

FIG. 11 is a flowchart illustrating an example of the element scaling process on an offset hexahedron;

FIG. 12 is a flowchart illustrating an example of an element rounding process;

FIG. 13 is a view illustrating an example of a synthesis screen;

FIG. 14 is a view corresponding to FIG. 13 and illustrating an example in which a hexahedron is selected as a geometric element;

FIG. 15 is a view corresponding to FIG. 13 and illustrating an example in which a type of a logical operation is selected;

FIG. 16 is a view illustrating an example of a synthesis processing table;

FIG. 17 is a view corresponding to FIG. 13 and illustrating an example in which a second geometric element is selected;

FIG. 18 is a view corresponding to FIG. 13 and illustrating an example in which a type of a logical operation of the second geometric element is selected;

FIG. 19 is a view corresponding to FIG. 13 and illustrating an example of a case where the type of the logical operation is subtraction;

FIG. 20 is a view corresponding to FIG. 13 and illustrating a state in which a computation is completed;

FIG. 21 is a flowchart illustrating an example of an exception determination process; and

FIG. 22 is a flowchart illustrating an example of a recalculation process.

### DETAILED DESCRIPTION

Hereinafter, embodiments of the invention will be described in detail with reference to the drawings. Note that the following preferred embodiments are described merely as examples in essence, and there is no intention to limit the invention, its application, or its use.

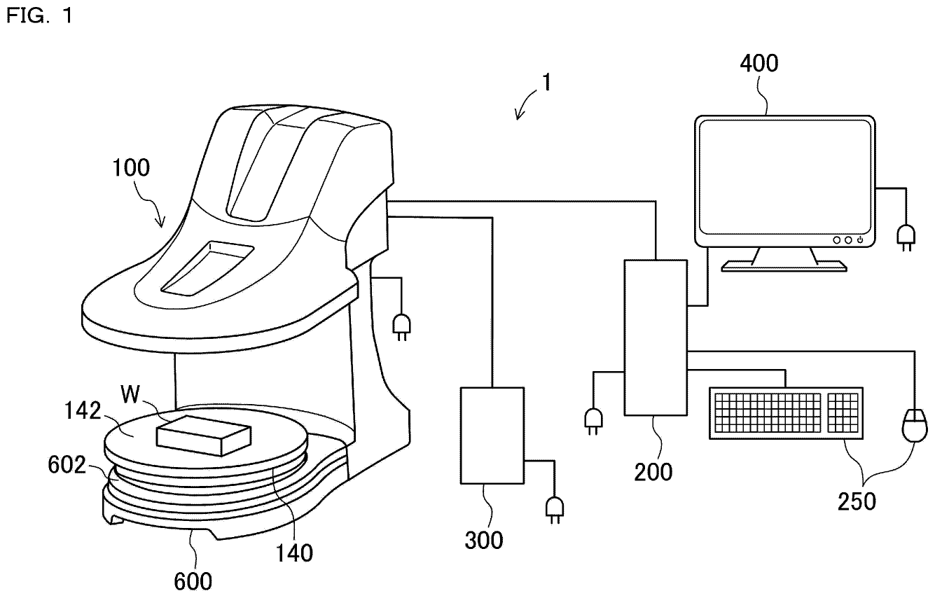

FIG. 1 is a diagram illustrating an overall configuration of a reverse engineering support apparatus 1 according to an embodiment of the invention. The reverse engineering support apparatus 1 is an apparatus that converts mesh data of a workpiece (measurement target object) W, obtained by measuring a shape of the workpiece W, into CAD data and outputs the CAD data. The reverse engineering support apparatus 1 is used, for example, in a case where CAD data of an existing product is acquired to perform next-generation model development and shape analysis on CAD and/or CAE, a case where a shape of a model or a mock-up in a product design is reflected in the product design, a case where a product to be a fitting source is designed based on a shape of a mating component to be fitted, a case where an improved design is made based on a shape of a prototype, or the like. Therefore, the workpiece W is, for example, an existing product, a model, a mock-up, a prototype, or the like.

Further, the reverse engineering support apparatus 1 is an apparatus capable of converting mesh data of the workpiece W into surface data and outputting the surface data. Since the surface data obtained by converting the mesh data of the workpiece W is output, it is possible to support a reverse engineering process and reverse engineering work of a user.

In the following description, when a shape of the workpiece W is measured, the workpiece W is irradiated with measurement light of a predetermined pattern, and coordinate information is acquired using a signal obtained from reflection light reflected by the surface of the workpiece W in acquiring the coordinate information of a surface of the workpiece W. For example, it is possible to use a measurement method using triangulation in which structured illumination is used to project the workpiece W as the measurement light of the predetermined pattern and a fringe projection image obtained from reflection light thereof is used. In the invention, however, the principle and configurations for acquiring the coordinate information of the workpiece W are not limited thereto, and other methods can also be applied.

The reverse engineering support apparatus 1 includes a measurement unit 100, a pedestal 600, a controller 200, a light source unit 300, and a display unit 400. The reverse engineering support apparatus 1 can perform structured illumination on the workpiece W by the light source unit 300, capture a fringe projection image to generate a depth image having the coordinate information, and can measure three-dimensional dimensions and shape of the workpiece W based on the depth image. The measurement using such fringe projection has an advantage that measurement time can be shortened since three-dimensional measurement can be performed without moving the workpiece W or an optical system such as a lens in a Z direction (height direction). Note that the display unit 400 is not necessarily included in the reverse engineering support apparatus 1. In this case, the display unit 400 to be controlled by a display control unit 276, which will be described later, is separately provided.

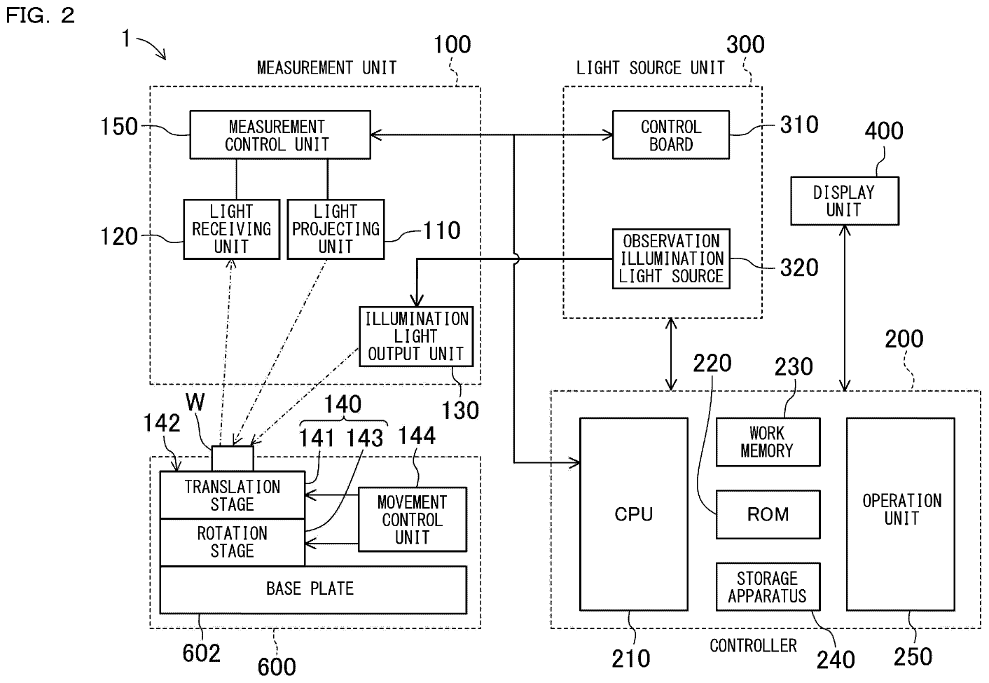

FIG. 2 illustrates a block diagram of the reverse engineering support apparatus 1 according to the embodiment of the invention. As illustrated in this drawing, the measurement unit 100 includes a light projecting unit 110, a light receiving unit 120, a measurement control unit 150, and an illumination light output unit 130. The light projecting unit 110 is a part that irradiates the workpiece W placed on a placement unit 140, which will be described later, with the measurement light having the predetermined pattern. The light receiving unit 120 is fixed in an attitude inclined with respect to a placement surface 142 which will be described later. The light receiving unit 120 receives the measurement light that has been emitted from the light projecting unit 110 and reflected by the workpiece W. When receiving the reflection light from the workpiece W, the light receiving unit 120 outputs a light reception signal indicating an amount of received light. The light receiving unit 120 can generate an observation image for observing the entire shape of the workpiece W by capturing an image of the workpiece W placed on the placement unit 140.

The light receiving unit 120 according to the embodiment includes a high-magnification light receiving unit and a low-magnification light receiving unit. The high-magnification light receiving unit is a part capable of capturing an image of the workpiece W in an enlarged manner as compared with the low-magnification light receiving unit. On the other hand, the low-magnification light receiving unit is a light receiving unit having a wider field of-view range than the high-magnification light receiving unit.

The pedestal 600 includes a base plate 602, the placement unit 140, and a movement control unit 144. The placement unit 140 is supported on the base plate 602 of the pedestal 600. The movement control unit 144 is a member that moves the placement unit 140. The movement control unit 144 may be provided on the controller 200 side, other than being provided on the pedestal 600 side.

The light source unit 300 is connected to the measurement unit 100. The light source unit 300 is a part that generates the measurement light and supplies the measurement light to the measurement unit 100. The controller 200 is a part that controls the measurement unit 100 and the like. The display unit 400 is connected to the controller 200, and is configured to display an image generated by the measurement unit 100 and to perform necessary setting, input, selection, and the like.

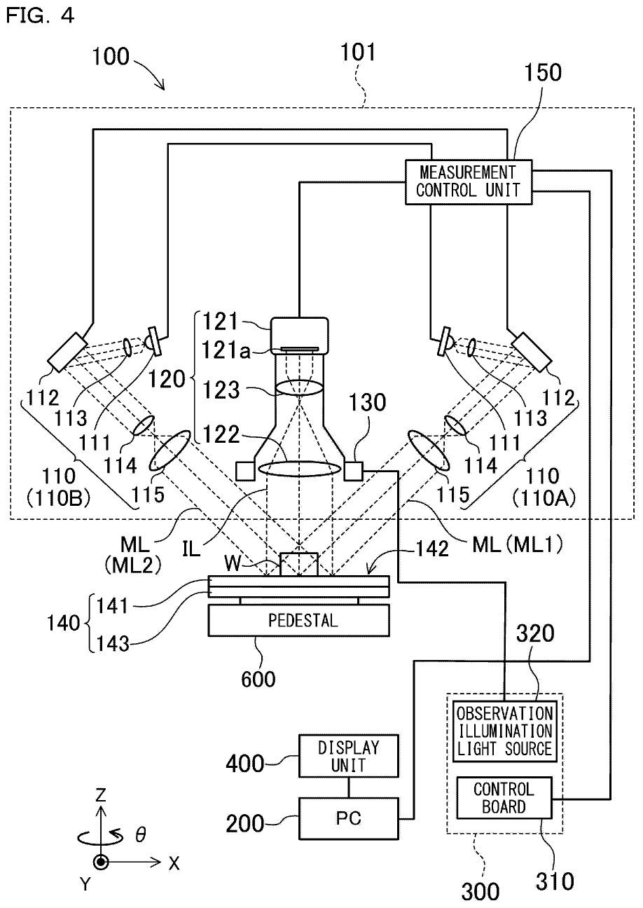

The placement unit 140 has the placement surface 142 on which the workpiece W is placed. As illustrated in FIG. 4, two directions orthogonal to each other in the placement surface 142 are defined as an X direction and a Y direction, and are indicated by arrows X and Y, respectively. A direction orthogonal to the placement surface 142 of the placement unit 140 is defined as the Z direction, and is indicated by an arrow Z. A direction of rotation about an axis parallel to the Z direction is defined as a θ direction, and is indicated by an arrow θ.

The placement unit 140 includes a rotation stage 143 that rotates the placement surface 142 about the axis extending in the Z direction, and a translation stage 141 that moves the placement surface 142 in the horizontal direction (X direction and Y direction). The translation stage 141 includes an X-direction movement mechanism and a Y-direction movement mechanism. Further, the rotation stage 143 has a θ-direction rotation mechanism. The placement unit 140 may include a fixing member (clamp) that fixes the workpiece W to the placement surface 142. Furthermore, the placement unit 140 may include a tilt stage having a mechanism rotatable about an axis parallel to the placement surface 142.

The movement control unit 144 controls rotational movement of the rotation stage 143 and parallel movement of the translation stage 141 according to measurement conditions set by the measurement condition setting unit 261 which will be described later. Further, the movement control unit 144 controls a movement operation of the placement unit 140 performed by a placement movement unit based on a measurement area set by the measurement condition setting unit 261 which will be described later.

The controller 200 includes a central processing unit (CPU) 210, a read only memory (ROM) 220, a work memory 230, a storage apparatus (storage unit) 240, an operation unit 250, and the like. The controller 200 can be configured using a personal computer (PC) or the like.

A configuration of the measurement unit 100 is illustrated in a block diagram of FIG. 4. The measurement unit 100 includes the light projecting units 110, the light receiving unit 120, the illumination light output unit 130, the measurement control unit 150, and a main body case 101 housing these. The light projecting unit 110 includes a measurement light source 111, a pattern generation unit 112, and a plurality of lenses 113, 114, and 115. The light receiving unit 120 includes a camera 121 and a plurality of lenses 122 and 123. When measurement is performed at different magnifications by providing a plurality of light receiving units, a light receiving unit 120a including a low-magnification camera 121 and a low-magnification lens, and a light receiving unit 120b including a high-magnification camera 121 and a high-magnification lens may be mounted. Note that the invention is not limited to this configuration, and the magnification may be made variable by switching a plurality of lenses for one camera 121, or the magnification may be made variable by providing a zoom lens for one camera 121.

The light projecting unit 110 is disposed obliquely above the placement unit 140. Although the measurement unit 100 includes the two light projecting units 110 in the example illustrated in FIG. 4, the measurement unit 100 may include a plurality of the light projecting units 110. Here, a first measurement light projecting unit 110A (on the right side in FIG. 4) capable of irradiating a measurement target object WK with first measurement light ML1 from a first direction and a second measurement light projecting unit 110B (on the left side in FIG. 4) capable of irradiating the measurement target object WK with second measurement light ML2 from a second direction different from the first direction are provided. The first measurement light projecting unit 110A and the second measurement light projecting unit 110B are disposed symmetrically with respect to an optical axis of the light receiving unit 120. Although not illustrated, it is also possible to project light to the workpiece W in different illumination directions by providing three or more light projecting units 110 or relatively moving the light projecting unit 110 and the placement unit 140 while using the common light projecting unit 110. Although the above example employs the configuration in which the plurality of light projecting units 110 are prepared and light is received by the common light receiving unit 120, conversely, a plurality of the light receiving units 120 may be prepared to receive light for the common light projecting unit 110. Furthermore, an irradiation angle of illumination light projected by the light projecting unit 110 with respect to the Z direction is fixed in this example, but this can also be made variable.

The first measurement light projecting unit 110A and the second measurement light projecting unit 110B include a first measurement light source and a second measurement light source, respectively, as the measurement light sources 111. These measurement light sources 111 are, for example, halogen lamps emitting white light. The measurement light source 111 may be a light source that emits monochromatic light, for example, another light source such as a blue light-emitting diode (LED) emitting blue light or an organic electroluminescence (EL). The light (hereinafter, referred to as “measurement light”) emitted from the measurement light source 111 is appropriately collected by the lens 113, and then, incident on the pattern generation unit 112.

A relative positional relationship among the light receiving unit 120, the light projecting units 110A and 110B, and the placement unit 140 is defined such that central axes of the light projecting units 110A and 110B and a central axis of the light receiving unit 120 intersect each other at a position where the disposition of the workpiece W on the placement unit 140 and depths of field of the light projecting units 110 and the light receiving unit 120 are appropriate. Further, a center of a rotation axis in the 0 direction coincides with the central axis of the light receiving unit 120, and thus, when the placement unit 140 rotates in the 0 direction, the workpiece W rotates in a field of view about the rotation axis without deviating from the field of view.

The pattern generation unit 112 reflects the light that has been emitted from the measurement light source 111 to be projected onto the workpiece W. The measurement light incident on the pattern generation unit 112 is converted into a preset pattern with a preset intensity (brightness) and emitted. The measurement light that has been emitted by the pattern generation unit 112 is converted into light having a diameter larger than an observable and measurable field of view of the light receiving unit 120 by the plurality of lenses 114 and 115, and then, is emitted to the workpiece W on the placement unit 140.

The pattern generation unit 112 is a member capable of switching between a light projection state in which the measurement light is projected to the workpiece W and a non-light projection state in which the measurement light is not projected to the workpiece W. Such a pattern generation unit 112 can be configured using, for example, a digital micromirror device (DMD) or the like. The pattern generation unit 112 using the DMD can be controlled by the measurement control unit 150 to be capable of switching between a reflection state in which the measurement light is reflected on an optical path as the light projection state and a light shielding state in which the measurement light is shielded as the non-light projection state.

The DMD is an element in which a large number of micromirrors (micro mirror surfaces) are arrayed on a plane. Each of the micromirrors can be individually switched between an ON state and an OFF state by the measurement control unit 150, and thus, a desired projection pattern can be configured by combining the ON states and the OFF states of the large number of micromirrors. As a result, it is possible to generate a pattern necessary for triangulation and measure a shape of the workpiece W. In this manner, the DMD functions as a projection pattern optical system that projects a periodic projection pattern for measurement onto the workpiece W during measurement. Further, the DMD is also excellent in response speed, and has an advantage of being operable at a higher speed than a shutter or the like.

Note that the example in which the DMD is used for the pattern generation unit 112 has been described in the above example, but the pattern generation unit 112 is not limited to the DMD, and other members can also be used in the invention. For example, a liquid crystal on silicon (LCOS) may be used as the pattern generation unit 112. Alternatively, a transmission amount of measurement light may be adjusted using a transmissive member instead of a reflective member. In this case, the pattern generation unit 112 is disposed on an optical path of the measurement light to switch between the light projection state in which the measurement light is transmitted and the light shielding state in which the measurement light is shielded. Such a pattern generation unit 112 can be configured using a liquid crystal display (LCD). Alternatively, the pattern generation unit 112 may be configured by a projection method using a plurality of line LEDs, a projection method using a plurality of optical paths, an optical scanner method including a laser and a galvanometer mirror, an accordion fringe interferometry (AFI) method using interference fringes generated by superimposing beams divided by a beam splitter, a projection method using gratings formed with a piezo stage, an encoder with high resolving power, and the like and a movement mechanism, or the like.

The light receiving unit 120 is disposed above the placement unit 140. The measurement light reflected upward of the placement unit 140 by the workpiece W is collected to form an image by the plurality of lenses 122 and 123 of the light receiving unit 120, and then received by the camera 121.

The camera 121 is, for example, a charge-coupled device (CCD) camera including an imaging element 121a. The imaging element 121a is, for example, a monochromatic charge-coupled device (CCD). The imaging element 121a may be another imaging element such as a complementary metal-oxide semiconductor (CMOS) image sensor. A color imaging element needs to include pixels respectively corresponding to light reception for red, green, and blue, and thus, has lower measurement resolving power as compared with a monochromatic imaging element, and has lower sensitivity because each of the pixels is necessarily provided with a color filter. Therefore, in the embodiment, the monochromatic CCD is adopted as the imaging element, and a color image is acquired by the illumination light output unit 130 performing irradiation with illuminations respectively corresponding to red (R), green (G), and blue (B) in a time division manner to capture images. With such a configuration, it is possible to acquire a color image of a measurement object without lowering the measurement accuracy.

Note that the color imaging element may be used as the imaging element 121a. In this case, although the measurement accuracy and the sensitivity are lower than those of the monochromatic imaging element, it becomes unnecessary to emit the illuminations respectively corresponding to RGB from the illumination light output unit 130 in a time division manner, and a color image can be acquired only by emitting white light, so that an illumination optical system can be simply configured. An analog electric signal (hereinafter, referred to as a “light reception signal”) corresponding to the amount of received light is output from each pixel of the imaging element 121a to the measurement control unit 150.

An analog/digital converter (A/D converter) and a first-in first-out (FIFO) memory (not illustrated) are mounted on the measurement control unit 150. The light reception signals output from the camera 121 are sampled at a constant sampling period and converted into digital signals by the A/D converter of the measurement control unit 150 under the control of the light source unit 300. The digital signals output from the A/D converter are sequentially accumulated in the FIFO memory. The digital signals accumulated in the FIFO memory are sequentially transferred to the controller 200 as pixel data.

The operation unit 250 of the controller 200 can include, for example, a keyboard, a pointing device, and the like. As the pointing device, for example, a mouse, a joystick, or the like is used.

The ROM 220 of the controller 200 stores a system program and the like. The work memory 230 of the controller 200 includes, for example, a random access memory (RAM) and is used for processing of various types of data. The storage apparatus 240 includes a solid-state drive, a hard disk drive, or the like. The storage apparatus 240 stores a reverse engineering program. Further, the storage apparatus 240 is used to save various types of data such as pixel data (image data), setting information, measurement conditions, and parameters given from the measurement control unit 150. The measurement conditions include, for example, various settings set by a scanner module 260, which will be described later, at the time of measuring a shape of the workpiece W, such as settings (a pattern frequency and a pattern type) of the light projecting unit 110 and a type (the low-magnification light receiving unit or the high-magnification light receiving unit) of the light receiving unit 120. Furthermore, the storage apparatus 240 can also store luminance information, coordinate information, and attribute information for each pixel constituting a measurement image.

The CPU 210 is a control circuit or a control element that processes a given signal or data, performs various computations, and outputs computation results. In the specification, a CPU means an element or a circuit that performs computations, and is not limited to a processor, such as a CPU for general-purpose PC, an MPU, a GPU or a TPU, but used in the sense of including a processor or a microcomputer such as a FPGA, an ASIC, and an LSI, or a chip set such as an SoC.

The CPU 210 generates image data based on pixel data given from the measurement control unit 150. The CPU 210 performs various processes on the generated image data using the work memory 230. For example, the CPU 210 generates measurement data representing a three-dimensional shape of the workpiece W included in a field of view of the light receiving unit 120 at a specific position of the placement unit 140 based on the light reception signal output from the light receiving unit 120. The measurement data is an image itself acquired by the light receiving unit 120. For example, when a shape of the workpiece W is measured by a phase shift method, a plurality of images constitute one piece of measurement data. Note that the measurement data may be point cloud data that is a set of points having three-dimensional position information, and the measurement data of the workpiece W can be acquired from the point cloud data. The point cloud data is data expressed by an aggregate of a plurality of points having three-dimensional coordinates.

In a case where measurement data of at least a part of the workpiece W is acquired as described above in measuring a shape of the workpiece W, movement of the placement unit 140 by the movement control unit 144 so as to acquire measurement data of another site of the workpiece W located around the measurement data of the acquired part and generation of measurement data of the another site of the workpiece W at this position are repeated, and a plurality of pieces of the obtained measurement data are synthesized, whereby synthetic measurement data including the entire shape of the workpiece W can be generated. A mode for generating the synthetic measurement data can be referred to as a linkage mode, and an image with a wider field of view than that in a case where an image is captured with a single field of view can be acquired by selecting the linkage mode.

The movement control unit 144 determines whether to execute only the rotation operation of the rotation stage 143 or to execute both the rotation operation of the rotation stage 143 and a parallel movement operation of the translation stage 141 based on the measurement data of at least a part of the workpiece W. As a result, an imaging range is automatically determined without the consciousness of the user according to an outer shape of the workpiece W, whereby the three-dimensional measurement becomes easy. Note that the movement control unit 144 can control the rotation stage 143 to rotate in a state in which the translation stage 141 has been moved in the XY directions, and then, the movement in the XY directions has been stopped, whereby a shape around the workpiece W can also be acquired.

The display unit 400 is a member configured to display the fringe projection image acquired by the measurement unit 100, the depth image generated based on the fringe projection image, a texture image captured by the measurement unit 100, various user interface screens, and the like. The display unit 400 is configured using, for example, an LCD panel or an organic electroluminescence (EL) panel. Furthermore, the display unit 400 can also be used as the operation unit 250 when being configured using a touch panel. Further, the display unit 400 can also display the image generated by the light receiving unit 120.

The light source unit 300 includes a control board 310 and an observation illumination light source 320. A CPU (not illustrated) is mounted on the control board 310. The CPU of the control board 310 controls the light projecting unit 110, the light receiving unit 120, and the measurement control unit 150 based on a command from the CPU 210 of the controller 200. Note that this configuration is an example, and other configurations may be used. For example, the control board may be omitted by controlling the light projecting unit 110 and the light receiving unit 120 by the measurement control unit 150 or controlling the light projecting unit 110 and the light receiving unit 120 by the controller 200. Alternatively, the light source unit 300 can also be provided with a power supply circuit configured to drive the measurement unit 100.

The observation illumination light source 320 includes, for example, LEDs of three colors that emit red light, green light, and blue light. Light of any color can be generated from the observation illumination light source 320 by controlling the luminance of the light emitted from each of the LEDs. Illumination light IL generated from the observation illumination light source 320 is output from the illumination light output unit 130 of the measurement unit 100 through a light guiding member (light guide). Note that light sources other than the LED, such as semiconductor laser (LD), halogen light, and HID, can be appropriately used for the observation illumination light source. In particular, in a case where an element capable of capturing a color image is used as the imaging element, a white light source can be used for the observation illumination light source.

The illumination light IL output from the illumination light output unit 130 irradiates the workpiece W with red light, green light, and blue light in a time-division manner. As a result, a color texture image can be obtained by synthesizing texture images respectively captured by these red light, green light, and blue light and be displayed on the display unit 400.

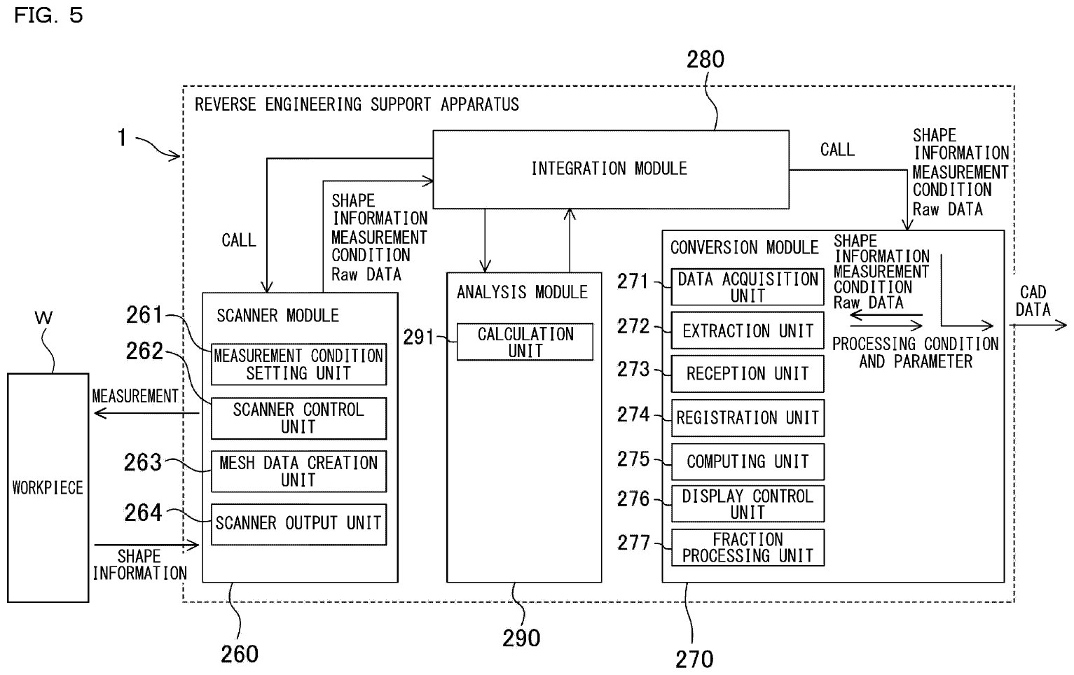

The controller 200 forms the scanner module 260, a conversion module 270, an integration module 280, and an analysis module 290 illustrated in FIG. 5 by the CPU 210, the ROM 220, the work memory 230, the storage apparatus 240, and the like. To give a brief description, the scanner module 260 is a part that measures a shape of the workpiece W to acquire image data of the workpiece W and creates mesh data of the workpiece W based on the image data although details of operations of the modules 260, 270, and 290 will be described later. The conversion module 270 is a part that converts the mesh data created by the scanner module 260 into CAD data. The CAD data is three-dimensional shape information including an analytic curved surface and a free curved surface, and includes surface data, solid data, data used for design, and the like. The surface data is data of a shape surface including a free curved surface and an analytic curved surface, such as side surface data and plane data of a cylinder. Further, the solid data is closed surface data without a hole, a geometric element having a volume such as a cylinder or a hexahedron, or a synthetic element obtained by combining these by a set operation.

The analysis module 290 is a part that acquires mesh data, extracts a plurality of geometric elements from the acquired mesh data, and calculates dimensions between the plurality of extracted geometric elements.

The integration module 280 is a part that transmits a signal and data from the scanner module 260 to the conversion module 270 and the analysis module 290, and transmits a signal and data from the conversion module 270 to the scanner module 260. In this example, the module can execute a plurality of computational processes in one unit, and can also be referred to as functional units, functional blocks, or the like, for example.

The scanner module 260 includes, for example, the measurement condition setting unit 261, a scanner control unit 262, a mesh data creation unit 263, a scanner output unit 264, and the like. The measurement condition setting unit 261 is a part that sets a measurement condition of a shape of the workpiece. The scanner control unit 262 is a part that controls the measurement unit 100 according to the measurement condition set by the measurement condition setting unit 261 to generate image data, and acquires measurement data of the workpiece W based on the generated image data. The mesh data creation unit 263 is a part that generates mesh data based on the image data of the workpiece W acquired by the scanner control unit 262. The scanner output unit 264 is a part that outputs the mesh data created by the mesh data creation unit 263 and additional data to the conversion module 270. The additional data is data including at least one of the measurement condition or data calculated from the measurement data of the workpiece W.

That is, the scanner module 260 controls the measurement unit 100, and generates all of conditions (a measurement model, a measurement magnification, a resolution, and the like) under which a shape of the workpiece W has been measured and raw data (for example, image data and the like) at the time of the measurement together with three-dimensional data. The three-dimensional data is mesh data including a plurality of polygons, and can also be referred to as polygon data. The polygon is data including information specifying a plurality of points and information indicating a polygonal surface formed by connecting the points, and can include, for example, information specifying three points and information indicating a triangular surface formed by connecting the three points. The mesh data and the polygon data can also be defined as data represented by aggregates of a plurality of polygons.

The conversion module 270 acquires mesh data and converts the acquired mesh data into CAD data.

The analysis module 290 includes a calculation unit 291 that acquires mesh data of the workpiece W, extracts a plurality of geometric elements from the acquired mesh data of the workpiece W, and calculates dimensions between the plurality of extracted geometric elements.

The reverse engineering support apparatus 1 has an all-in-one form encompassing all the respective modules 260 and 270 for measurement, processing determination, and conversion, and transmission and reception of data between the modules 260 and 270 can also be automated.

In a case where the transmission and reception of data between the modules 260 and 270 is automated, the integration module 280 that integrates the modules 260 and 270 is provided. As a result, each of the modules 260 and 270 has a form of proceeding processing designated by the integration module 280. The role of the integration module 280 can also be consolidated into any of the modules 260 and 270 that execute the measurement, the processing determination, the CAD conversion, and the like. Further, each function of the analysis module 290 can also be integrated into the scanner module 260.

### (Details of Conversion Module)

As illustrated in FIG. 5, the conversion module 270 includes, for example, a data acquisition unit 271, an extraction unit 272, a reception unit 273, a registration unit 274, a computing unit 275, the display control unit 276, and a fraction processing unit 277. Note that the data acquisition unit 271, the extraction unit 272, the reception unit 273, the registration unit 274, the computing unit 275, the display control unit 276, and the fraction processing unit 277 may be divided into a plurality of modules.

Here, an outline of operations of the data acquisition unit 271, the extraction unit 272, the reception unit 273, the registration unit 274, the computing unit 275, and the display control unit 276 will be described. The data acquisition unit 271 is a part that acquires mesh data of the workpiece W measured by the scanner module 260. The extraction unit 272 is a part that extracts a plurality of geometric elements from the mesh data of the workpiece W acquired by the data acquisition unit 271. The reception unit 273 is a part that receives an operation of the operation unit 250 performed by the user, and is configured to be capable of receiving an input for extracting a geometric element with respect to the mesh data of the workpiece W acquired by the data acquisition unit 271. The extraction unit 272 obtains a group of polygons for generating geometric elements based on the user input received by the reception unit 273, and then extracts a geometric element such as a cylinder, a cone, a sphere, or a hexahedron by least square approximation. The extraction unit 272 can set element scaling such as enlarging a specific face of the extracted geometric element to be offset to a synthesis target element.

The reception unit 273 is a part that receives, a case where a plurality of geometric elements are extracted by the extraction unit 272, selection of one geometric element from among the plurality of extracted geometric elements and receives selection of a type of a logical operation for the one geometric element. Examples of the type of the logical operation include addition, subtraction, multiplication, and the like.

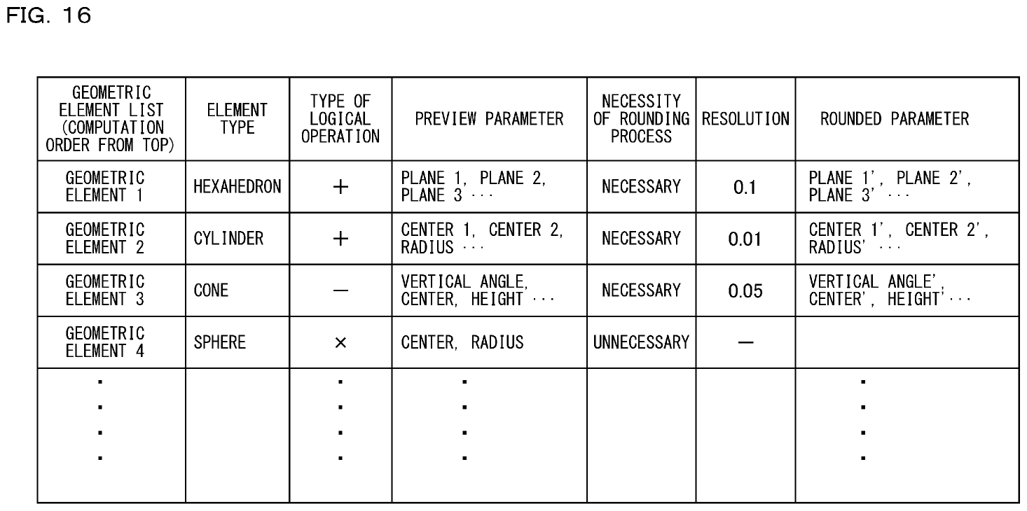

The registration unit 274 is configured to be capable of registering a plurality of records in which the type of the logical operation received by the reception unit 273 is associated with the geometric element received by the reception unit 273 in a synthesis processing table (an example thereof is illustrated in FIG. 16). The type of the logical operation can be displayed as a sign of “+” in the case of addition, can be displayed as a sign of “−” in the case of subtraction, and can be displayed as a sign of “×” in the case of multiplication. Thus, the record can also be referred to as a signed geometric element record.

The computing unit 275 is a part that creates a synthetic element by executing a logical operation of a geometric element based on a type of the logical operation associated with each record for each of the records included in the synthesis processing table and registered by the registration unit 274. The display control unit 276 is a part that causes the display unit 400 to display the synthetic element created by the computing unit 275.

Here, a case where the reception unit 273 receives a geometric element extracted by the extraction unit 272 and selection of a type of a logical operation of the geometric element and the computing unit 275 performs the logical operation of the geometric element will be mainly described, but a target of the logical operation is not limited to the geometric element, and may be surface data or solid data having a free curved surface extracted from mesh data. Further, the target of the logical operation may be composite surface data or composite solid data which has been subjected to a logical operation.

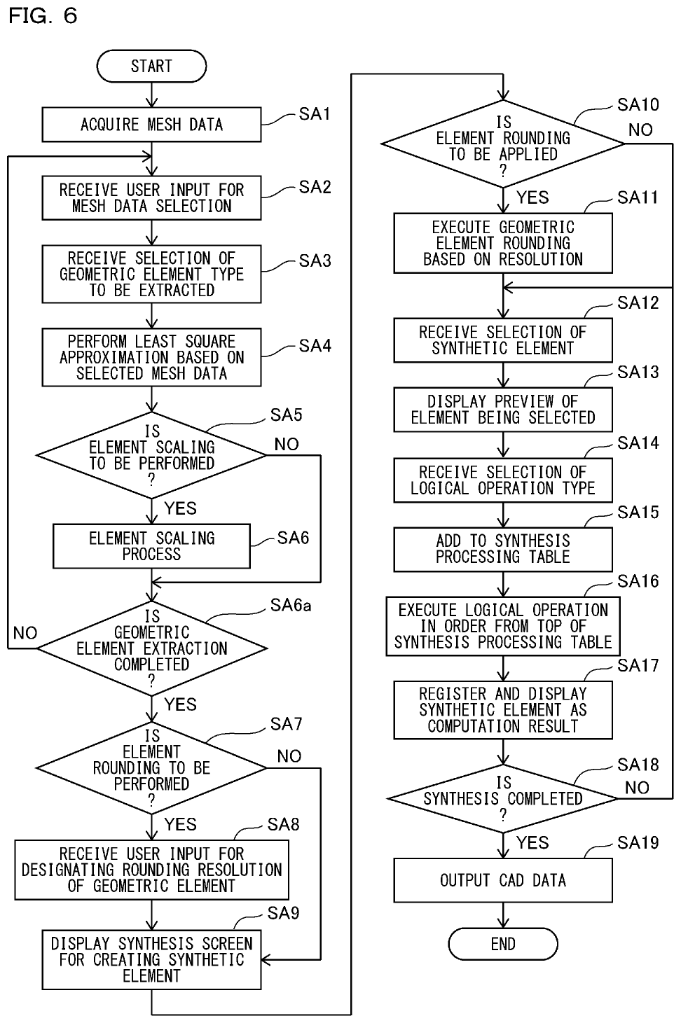

Details of operations of the data acquisition unit 271, the extraction unit 272, the reception unit 273, the registration unit 274, the computing unit 275, the display control unit 276, and the fraction processing unit 277 will be described with reference to a flowchart illustrated in FIG. 6. In step SA1, the data acquisition unit 271 acquires mesh data generated by the mesh data creation unit 263 of the scanner module 260.

The data acquisition unit 271 may acquire mesh data generated by a scanner (not illustrated) other than the scanner module 260. In this case, the reverse engineering support apparatus 1 does not necessarily include the scanner module 260.

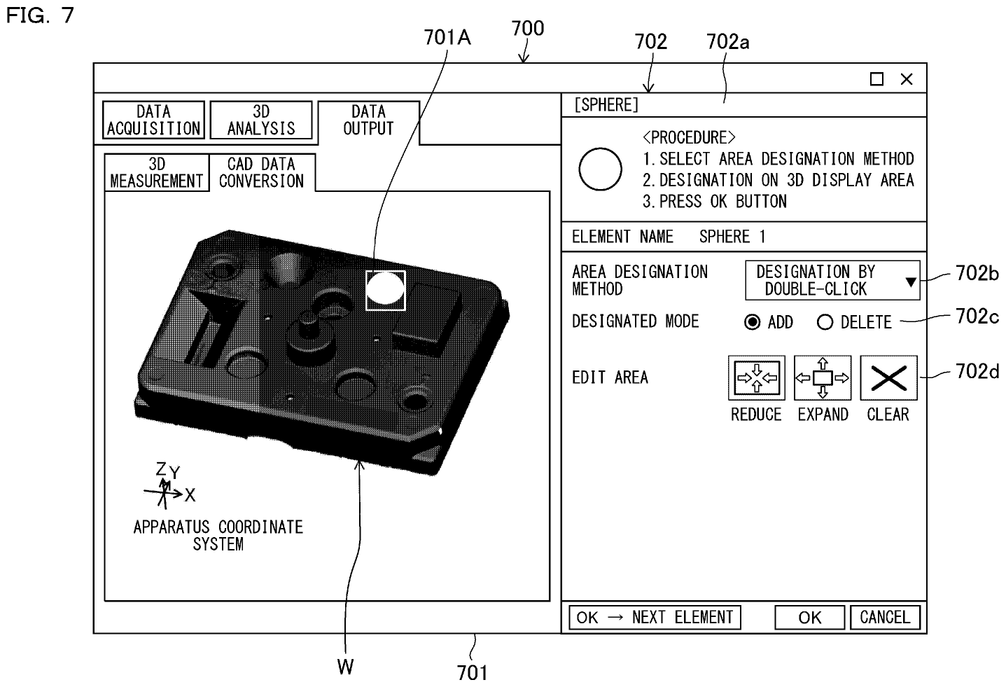

In step SA2, the reception unit 273 receives a user input for mesh data selection. In step SA3, selection of a geometric element type to be extracted by the user is received. For example, an element setting screen 700 as illustrated in FIG. 7 is generated by the display control unit 276 and displayed on the display unit 400. The element setting screen 700 is provided with a mesh data display area 701 for displaying the mesh data acquired by the data acquisition unit 271 and a geometric element extraction screen 702 for extracting a geometric element by the extraction unit 272. The geometric element extraction screen 702 is provided with a procedure display area 702a in which a geometric element extraction procedure is displayed, an area designation method selection section 702b, a designation mode selection section 702c, and an area editing selection section 702d. In the procedure display area 702a, a diagram representing a geometric element to be extracted is also displayed, and a case where a “sphere” is selected as the geometric element type is illustrated in this example. In the area designation method selection section 702b, a method for designating an area by the user can be selected from among a plurality of methods. In the designation mode selection section 702c, designation of addition or designation of deletion can be selected. In the area editing selection section 702d, reduce, expand, and clear (erase) can be selected as an area editing method.

In step SA4 illustrated in FIG. 6, the extraction unit 272 extracts the geometric element by executing least square approximation based on mesh data of the geometric element type received in step SA3. Specifically, in the mesh data of the mesh data display area 701 of the element setting screen 700 illustrated in FIG. 7, a frame line 701A surrounding an area set on the geometric element extraction screen 702 is displayed. Since the “sphere” is selected as the geometric element type, a sphere is extracted as the geometric element included in the area surrounded by the frame line 701A. A size, a position, and a shape of the frame line 701A can be freely changed by the user operating the operation unit 250.

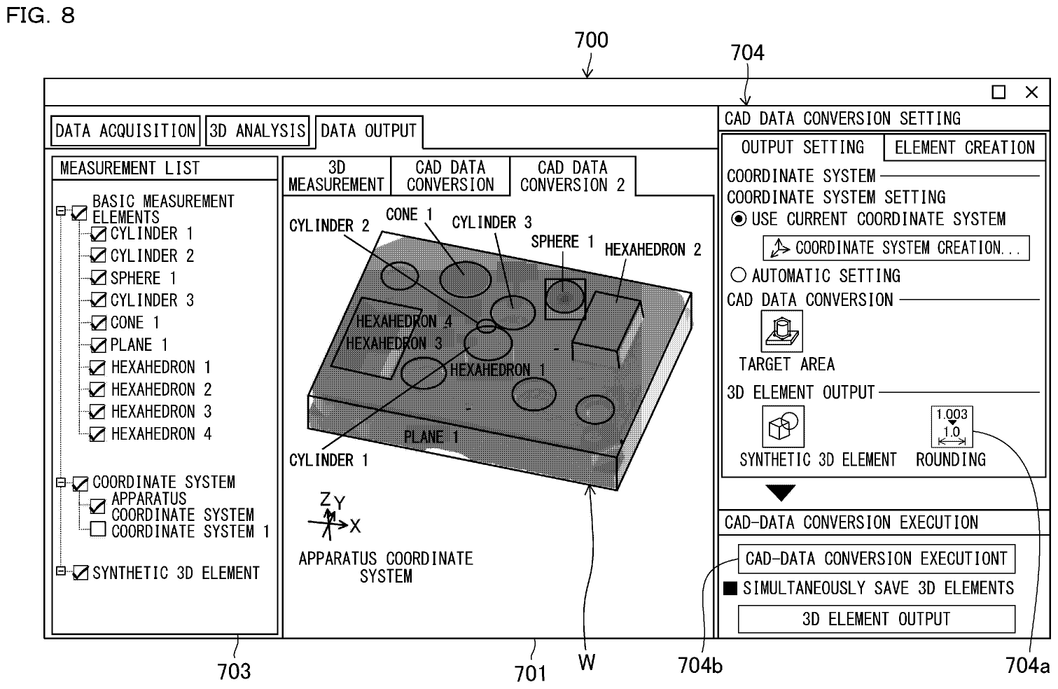

FIG. 8 illustrates the element setting screen 700 in a case where a plurality of geometric elements are extracted. As illustrated in the mesh data display area 701, in a case where a plurality of cylinders are extracted, identification information for enabling one cylinder to be identified from the other cylinders is assigned to a name of a geometric element, and in this example, numbers such as 1 and 2 are assigned to names of the geometric elements as the identification information. For each of a hexahedron, a sphere, a cone, a plane, and the like, identification information for enabling one geometric element to be identified from another geometric element is given to a name of the geometric element as in the case of the cylinder.

The element setting screen 700 is provided with a list display area 703 for displaying the extracted geometric elements in a list form. Names and identification information of the geometric elements displayed in the list display area 703 are in correspondence with the names and the identification information of the geometric elements displayed in the mesh data display area 701. Further, the element setting screen 700 is provided with a setting area 704 that enables the user to perform various settings for conversion into CAD data. The setting area 704 may be provided with a CAD data conversion execution icon 704b for converting a geometric element selected in the list display area 703 into CAD data. When the reception unit 273 receives an operation input of the CAD data conversion execution icon 704b, the computing unit 275 converts the geometric element selected in the list display area 703 into CAD data.

In step SA5 illustrated in FIG. 6, the extraction unit 272 determines whether or not to perform element scaling on the geometric element extracted in step SA4. In a case where it is determined to perform the element scaling in step SA5, the process proceeds to step SA6 to execute an element scaling process. On the other hand, in a case where it is determined not to perform the element scaling in step SA5, step SA6 is skipped, and the process proceeds to step SA6a.

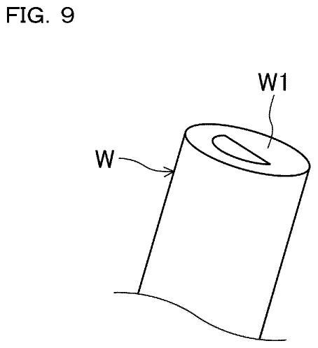

The reason why the element scaling process is executed in step SA6 is as follows. That is, for example, CAD data illustrated in FIG. 9 indicates that the workpiece W is data of a hollow round bar, and a circular opening should be originally formed on an end face W1 of the workpiece W. However, when cutting is performed between two geometric shapes having substantially matching faces at the time of executing a set operation, the cutting does not fall within a calculation tolerance, so that a surface of the workpiece W slightly remains, and a thin skin that blocks a part of the opening remains. Since the reusability of the CAD data may be significantly deteriorated if a part of the surface remains as described above, the element scaling process is executed to prevent a part of the surface from remaining.

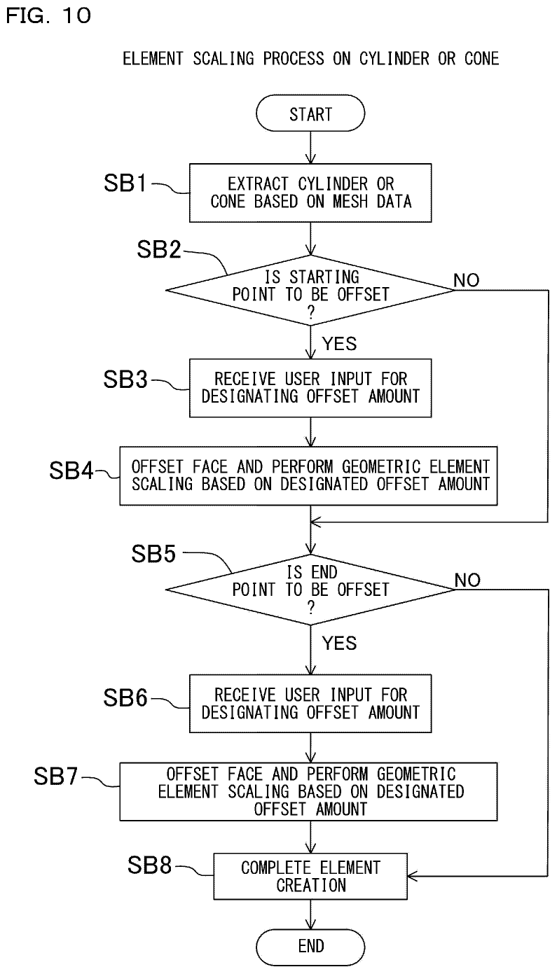

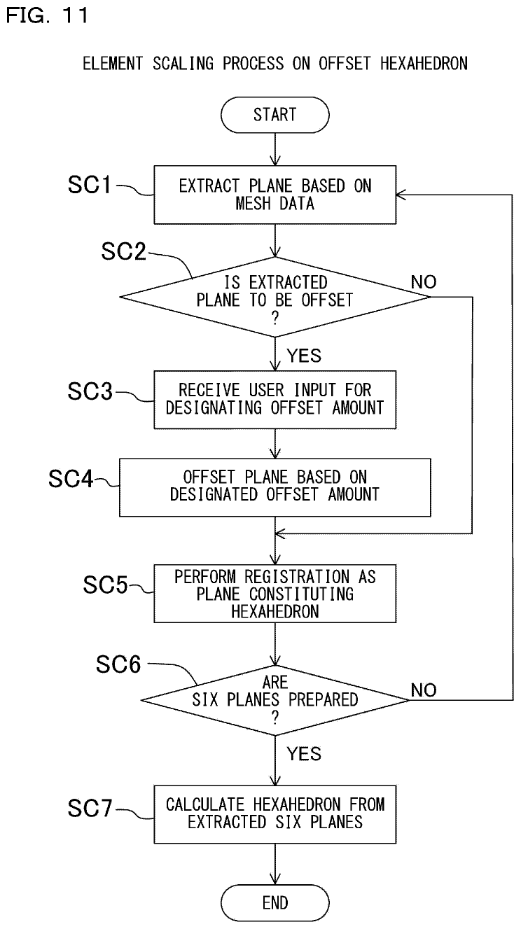

Details of the element scaling process are illustrated in FIGS. 10 and 11. FIG. 10 is an example of the element scaling process when a geometric element is a cylinder or a cone, and FIG. 11 is an example of the element scaling process when a geometric element is an offset hexahedron. In step SB1 of FIG. 10, the extraction unit 272 extracts a cylinder or a cone based on mesh data. In step SB2, the extraction unit 272 determines whether or not the reception unit 273 has received a user input for offsetting a start point. In a case where the start point is to be offset, the process proceeds to step SB3, the reception unit 273 receives a user input for designating an offset amount, and the received offset amount is temporarily stored in the storage apparatus 240 or the like. In a case where the start point is not to be offset, steps SB3 and SB4 are skipped from step SB2, and the process proceeds to step SB5.

In step SB4, the extraction unit 272 reads the offset amount designated in step SB3, and the extraction unit 272 offsets a face based on the read offset amount to scale up or down the geometric element. In step SB5, the extraction unit 272 determines whether or not the reception unit 273 has received a user input for offsetting an end point. In a case where the end point is to be offset, the process proceeds to step SB6, the reception unit 273 receives a user input for designating an offset amount, and the received offset amount is temporarily stored in the storage apparatus 240 or the like. In a case where the end point is not to be offset, steps SB6 and SB7 are skipped from step SB5, and the process proceeds to step SB8.

In step SB7, the extraction unit 272 reads the offset amount designated in step SB6, and the extraction unit 272 offsets a face based on the read offset amount to scale up or down the geometric element. In step SB8, the extraction unit 272 completes element creation.

In this manner, in the case of the element scaling process on a cylinder or a cone, an offset amount by any distance can be designated for each of a start point face and an end point face. By designating the offset amount by any distance for each of the start point face and the end point face, it is possible to create a geometric element as desired by the user even in the case of a blind hole shape which is a geometric element for which it is desired to fix an end point on one side and scale up or down an element on the other side. Flexible element extraction can be performed by inputting the same value as the offset amount for the start point face and the end point face in the case of a through-hole formed in the workpiece W or the like, designating the offset amount only on one side in the example illustrated in FIG. 9, and the like. It is not possible to offset a vertex side of a truncated cone by an amount beyond the vertex.

On the other hand, in a case where a geometric element is an offset hexahedron, a designated specific plane among six planes constituting a hexahedron can be offset by any distance. Hereinafter, the case where the geometric element is the offset hexahedron will be specifically described. In step SC1 of FIG. 11, the extraction unit 272 extracts a plane based on mesh data. In step SC2, the extraction unit 272 determines whether or not the reception unit 273 has received a user input for offsetting the plane extracted in step SC1. In a case where the plane extracted in step SC1 is to be offset, the process proceeds to step SC3, the reception unit 273 receives a user input for designating an offset amount, and the received offset amount is temporarily stored in the storage apparatus 240 or the like. In a case where the plane extracted in step SC1 is not to be offset, steps SC3 and SC4 are skipped from step SC2, and the process proceeds to step SC5.

In step SC4, the extraction unit 272 reads the offset amount designated in step SC3, and the extraction unit 272 offsets the plane based on the read offset amount. In step SC5, the extraction unit 272 registers the plane offset in step SC4 as a plane constituting the hexahedron. In the case where the plane is not to be offset, the extraction unit 272 registers the plane extracted in step SC1 as a plane constituting the hexahedron.

In step SC6, the extraction unit 272 determines whether or not the six planes constituting the hexahedron are prepared. In a case where the six planes are not prepared, the process proceeds to step SC1, and another plane is extracted based on the mesh data. In a case where the six planes are prepared, the process proceeds to step SC7, and the extraction unit 272 calculates the hexahedron from the extracted six planes.

Note that a method of designating an “offset amount” for designating a scaling amount from a designated point has been described here, but methods such as “percentage designation” of designating a ratio with respect to a distance from a specific point (the center of a geometric element or the like) as the scaling amount or “any point designation” of performing scaling until a click input by the user is received may be used.

When the element scaling process in step SA6 of the flowchart illustrated in FIG. 6 is completed as described above, the process proceeds to step SA6a. In step SA6a, it is determined whether or not the geometric element extraction is completed. In a case where the geometric element extraction is not completed, the process returns to step SA2. When the geometric element extraction is completed, the process proceeds to step SA7. In this manner, a plurality of geometric elements can be extracted in this example.

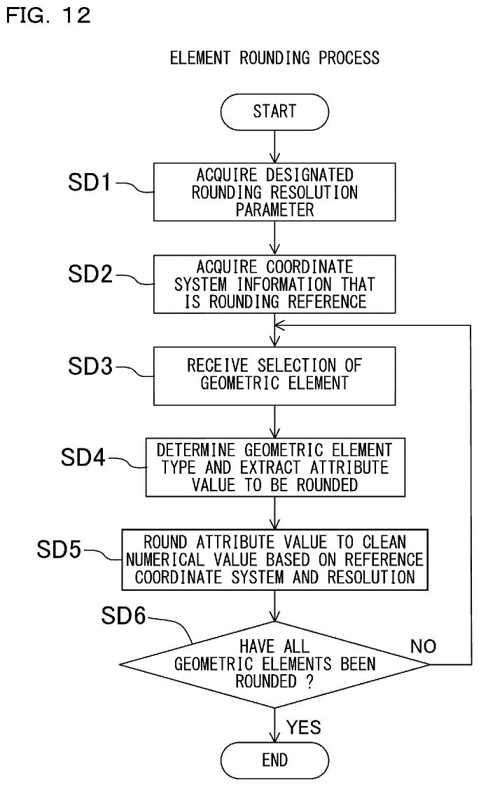

In step SA7, the extraction unit 272 determines whether or not to perform element rounding on the geometric element. An element rounding process is performed according to a flowchart illustrated in FIG. 12. The determination as to whether or not to perform the element rounding can reflect an intention of the user.

In the setting area 704 of the element setting screen 700 illustrated in FIG. 8, a resolution designation icon 704a for receiving designation of a rounding resolution is provided. When the user operates the resolution designation icon 704a, it is determined to perform the element rounding process in step SA7. In a case where it is determined to perform the element rounding process, the process proceeds to step SA8. On the other hand, in a case where it is determined not to perform the element rounding process, step SA8 is skipped, and the process proceeds to step SA9. The element rounding process is to perform fraction processing on a coordinate value, a dimensional value, and an angle component of geometric element data extracted by the extraction unit 272, and is executed by the fraction processing unit 277.

That is, since the mesh data is faithfully constructed to be true to the real workpiece W, attribute information of the coordinate value and the dimensional value (a length, a radius, an angle, or the like) of the geometric element extracted from the mesh data by the extraction unit 272 is a fractional numerical value. Meanwhile, CAD data created by a design act on CAD software is generally a non-fractional value in many cases, and thus, creating CAD data after processing a fraction of the attribute information leads to improvement of the reusability when the CAD data is used on the CAD software side. When this element rounding process is combined with a logical operation of the geometric element, for example, a position and a diameter of a through-hole, a distance between inner walls of a concave shape, and the like can be rounded cleanly without any fraction, and CAD data with higher reusability can be generated.

In step SA8, the reception unit 273 receives a user input for designating a rounding resolution parameter for the geometric element, and the received resolution parameter is temporarily stored in the storage apparatus 240 or the like. For example, the user can designate any rounding resolution parameter by operating the resolution designation icon 704a illustrated in FIG. 8.

The element rounding illustrated in steps SA7 to SA9 may be uniformly executed on the geometric elements extracted by the extraction unit 272, or may be individually executed on each of the geometric elements extracted by the extraction unit 272. In a case where the element rounding is individually executed for each of the geometric elements extracted by the extraction unit 272, the necessity of the rounding process and the resolution at the time of the rounding process may be stored in the storage apparatus 240 or the like in association with each other for each of the geometric elements.

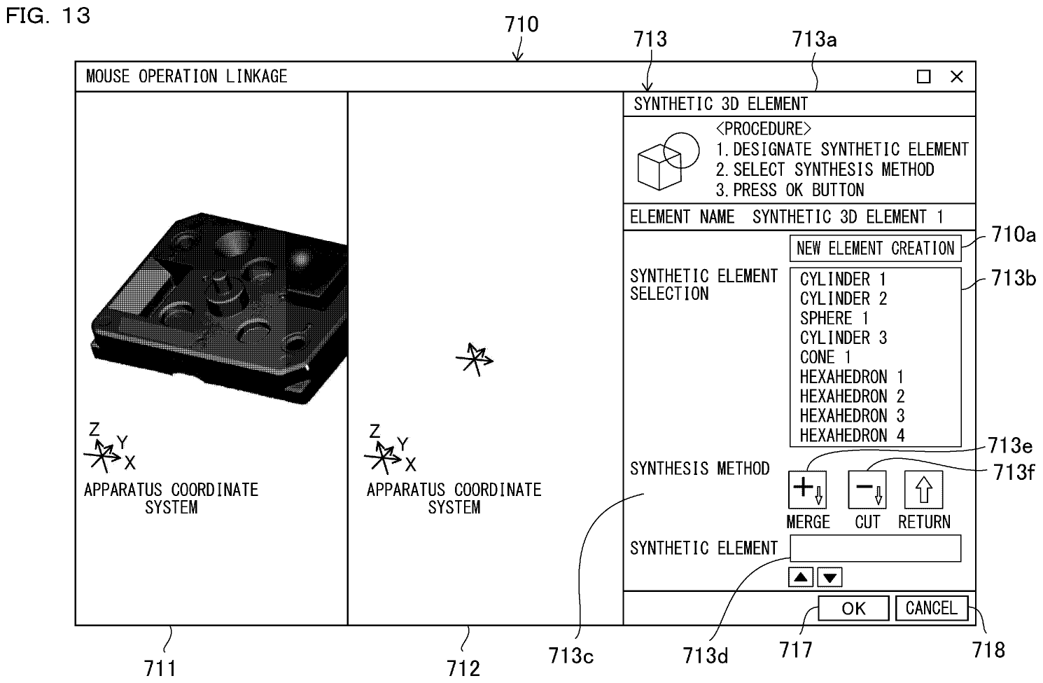

In step SA9, the display control unit 276 generates a synthesis screen 710 (illustrated in FIG. 13) for creating a synthetic element, and displays the synthesis screen 710 on the display unit 400. The synthesis screen 710 includes a mesh display area 711 for displaying mesh data acquired by the data acquisition unit 271, a synthetic element display area 712 for displaying a synthetic element computed by the computing unit 275, and a candidate display area 713 for displaying a plurality of geometric elements extracted by the extraction unit 272 as synthesis candidates.

The geometric element extraction screen 702 as illustrated in FIG. 7 can also be displayed on the synthesis screen 710. For example, as illustrated in FIG. 13, the synthesis screen 710 is provided with an OK button 717 that is operated to execute creation of a synthetic element after selection of a geometric element by the user is completed, and a cancel button 718 for canceling the creation of a synthetic element by the user. The reception unit 273 is configured to receive that the user has operated the OK button 717 or the cancel button 718 via the operation unit 250. When the reception unit 273 receives the operation of the OK button 717, a synthetic element is created by the computing unit 275. When the synthetic element is created by the computing unit 275, the display control unit 276 may add and display a “synthetic 3D element” in the list display area 703 as illustrated in FIG. 8. Further, the synthesis screen 710 may be provided with a new creation button 710a for creating a new geometric element, and the display control unit 276 may transition to the geometric element extraction screen 702 when the reception unit 273 receives the operation of the new creation button 710a. When an operation input of the CAD data conversion execution icon 704b illustrated in FIG. 8 is received by the reception unit 273 in a state in which the synthetic element is created by the computing unit 275 and a newly created “synthetic 3D element” is selected, the computing unit 275 can handle the synthetic 3D element as a 3D element similarly to other geometric elements and convert a geometric element including the synthetic 3D element into CAD data.

The candidate display area 713 is provided with a procedure display area 713a in which a procedure of a method of selecting a geometric element constituting a synthetic element is displayed, a synthetic element selection area 713b in which a plurality of geometric elements extracted by the extraction unit 272 are displayed in a list form, a type selection area 713c for selecting a type of a logical operation, and a selected element display area 713d in which a selected geometric element is displayed. In the synthetic element selection area 713b, each geometric element is displayed in a display form in which identification information is assigned to a name of the geometric element. In the synthetic element selection area 713b, it is possible to collectively display geometric elements for each type, and for example, it is possible to display all extracted cylinders on the top and display all extracted hexahedrons below the cylinders.

The reception unit 273 is configured to be capable of receiving selection of one geometric element from among a plurality of geometric elements displayed in the synthetic element selection area 713b. Specifically, when the user operates the operation unit 250 to select one geometric element displayed in the synthetic element selection area 713b, the reception unit 273 specifies the one geometric element selected by the selection operation by the user, and the reception unit 273 receives the selection of the specified one geometric element.

In step SA10, the fraction processing unit 277 determines whether or not to apply an element rounding process. In a case where the element rounding process is to be applied, the process proceeds to step SA11, and the fraction processing unit 277 acquires a resolution parameter designated by the user and executes a rounding process on a geometric element based on the acquired parameter.

The element rounding process executed in step SA11 will be specifically described with reference to the flowchart illustrated in FIG. 12. In step SD1, the rounding resolution parameter received in step SA8 of FIG. 6 is acquired by the fraction processing unit 277. In step SD2, the fraction processing unit 277 acquires coordinate system information that is a rounding reference. In step SD3, the reception unit 273 receives selection of one geometric element from among a plurality of geometric elements displayed in the synthetic element selection area 713b.

In step SD4, the fraction processing unit 277 determines a type of the geometric element selected in step SD3 and extracts an attribute value to be rounded. In step SD5, the fraction processing unit 277 rounds the attribute value extracted in step SD4 to a clean numerical value, that is, a non-fractional numerical value based on a reference coordinate system and the resolution parameter.

In step SD6, it is determined whether or not the element rounding process has been executed for all the geometric elements. In a case where it is determined in step SD6 that the element rounding process has not been executed for all the geometric elements, the process proceeds to step SD3, and the reception unit 273 receives selection of another geometric element. In this manner, the element rounding process is executed for all the geometric elements. In this example, since the attribute values of the individual geometric elements are rounded with respect to the same coordinate system, not only the attribute value of the single geometric element but also the relative positional relationship among them can be rounded. As a result, it is possible to have a clean value without a fraction as the entire synthetic element after a computation. Further, since all the geometric elements are rounded in advance at this stage, the processing cost in synthetic element creation, which will be described later, can be reduced. As a result, a set operation can be speeded up, and a computation result can be confirmed quickly, and thus, trial and error can be easily performed. Note that the case where the element rounding process is executed for all the geometric elements has been described as an example here, but the element rounding process may be executed only for a geometric element that requires the element rounding process. Details of this case will be described later.

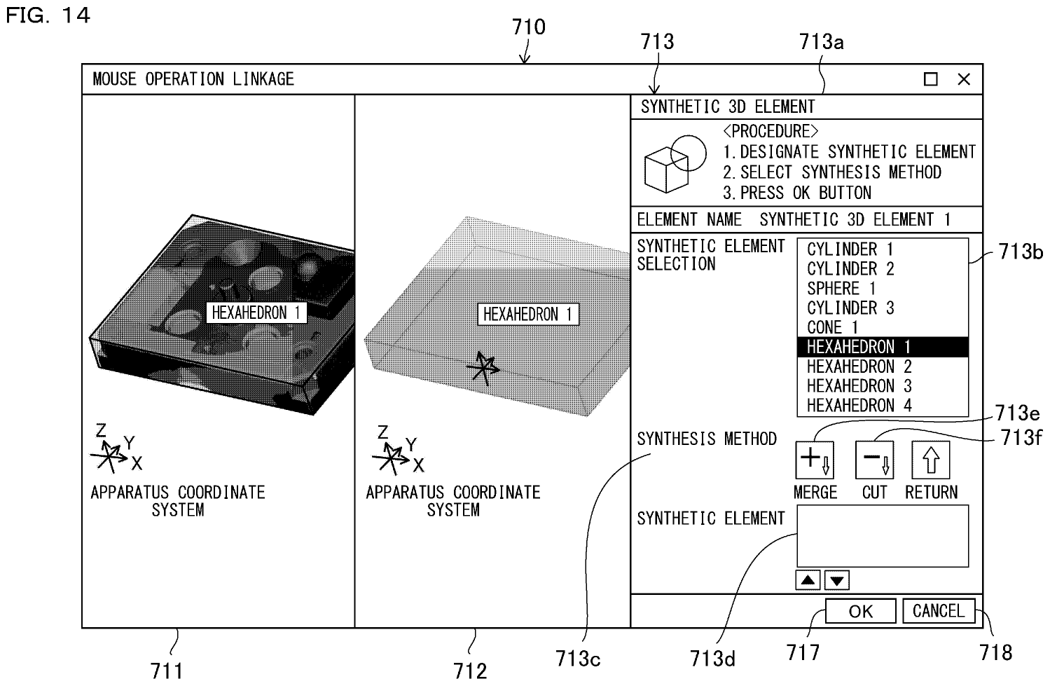

In a case where it is determined in step SD6 that the element rounding process has been executed for all the geometric elements, the process proceeds to step SA12 of the flowchart illustrated in FIG. 6. In step SA12, when the user selects a desired geometric element from among the plurality of geometric elements displayed in the synthetic element selection area 713b of the synthesis screen 710 illustrated in FIG. 14, the reception unit 273 receives the selection of the geometric element. In the example illustrated in FIG. 14, “Hexahedron 1” is selected as the geometric element, and thus, “Hexahedron 1” is displayed in the selected element display area 713d.

As illustrated in FIG. 14, in response to selection of one geometric element from the candidate display area 713, the display control unit 276 generates the synthesis screen 710 in which the one geometric element is superimposed on each of the mesh display area 711 and the synthetic element display area 712, and displays the synthesis screen on the display unit 400. In the synthesis screen 710 illustrated in FIG. 14, a display color of a geometric element and a display color of mesh data are changed. That is, the display control unit 276 generates the synthesis screen 710 in which one geometric element is identifiably displayed by making a display color of the one geometric element different from a display color of the mesh data displayed in the mesh display area 711, and displays the synthesis screen 710 on the display unit 400.

Further, a display color of one geometric element selected from the candidate display area 713 and the display color of the mesh data are changed in the synthesis screen 710 illustrated in FIG. 14. Specifically, the display control unit 276 generates the synthesis screen 710 in which one geometric element is identifiably displayed by making a display color of the one geometric element different from a display color of a synthetic element displayed in the synthetic element display area 712, and displays the synthesis screen 710 on the display unit 400. Changing the display color also includes changing the density of the display color and changing the brightness of the display color. The same applies hereinafter. Furthermore, a display color of one geometric element selected from the candidate display area 713 may be made different according to a type of a logical operation associated with the one geometric element. Specifically, a geometric element for which addition is designated as the type of the logical operation may be displayed in a first display color, and a geometric element for which subtraction is designated as the type of the logical operation may be displayed in a second display color.

In step SA13, the display control unit 276 displays a preview of the geometric element selected in step SA12 on the display unit 400. Specifically, the display control unit 276 generates a preview image of the geometric element selected in step SA12 and displays the preview image in the synthetic element display area 712. In this example, since “Hexahedron 1” is selected as the synthetic element, “Hexahedron 1” is previewed on the display unit 400. Also in the preview display, the display color of the geometric element is different from the display color of the mesh data, and the geometric element can be easily identified.

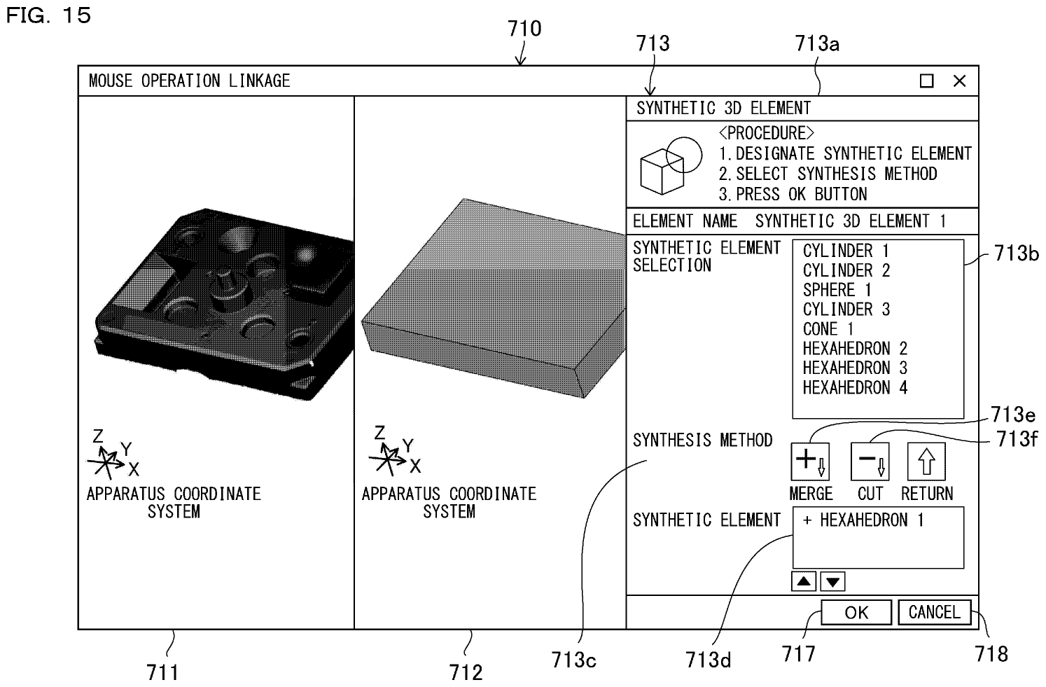

In step SA14, the reception unit 273 receives selection of a logical operation type of the geometric element received in step SA12. That is, as illustrated in FIG. 15, the type selection area 713c includes a first icon 713e for designating addition as one logical operation type of the geometric element received by the reception unit 273 and a second icon 713f for designating subtraction as one logical operation type of the geometric element received by the reception unit 273. Although not illustrated, the type selection area 713c may include a third icon for designating multiplication as one logical operation type of the geometric element received by the reception unit 273. That is, in the type selection area 713c, an icon for designating one logical operation type of the geometric element received by the reception unit 273 is provided.

When the user operates the first icon 713e by the operation unit 250, the reception unit 273 detects that the first icon 713e has been operated, and receives the selection of addition as the logical operation type. Further, when the user operates the second icon 713f by the operation unit 250, the reception unit 273 detects that the second icon 713f has been operated, and receives the selection of subtraction as the logical operation type. When the icon for designating multiplication is operated, the reception unit 273 receives the selection of multiplication as the logical operation type.

The example illustrated in FIG. 15 illustrates a case where addition is selected, and “+” indicating that addition is selected as a type of a logical operation is displayed next to “Hexahedron 1” in the selected element display area 713d. That is, “Hexahedron 1” which is the geometric element and “+” which is the type of the logical operation are displayed in the selected element display area 713d in a state of being associated with each other.

Although the display color of the geometric element and the display color of the mesh data are changed such that the geometric element can be identified in FIG. 14 before a computation, a display color of the geometric element and a display color of the mesh data are made the same in FIG. 15 illustrating a state in which the computation is completed. That is, when the logical operation of the identifiably displayed geometric element is executed by the computing unit 275, the display control unit 276 generates the synthesis screen 710 in which the display color of the identifiably displayed geometric element is made the same as the display color of the mesh data displayed in the mesh display area 711, and displays the synthesis screen 710 on the display unit 400. Note that the display color of the geometric element and the display color of the mesh data may remain different.

In FIG. 15 illustrating the state in which the computation is completed, the display color of the geometric element and a display color of the synthetic element displayed in the synthetic element display area 712 may be the same. That is, when the logical operation of the identifiably displayed geometric element is executed by the computing unit 275, the display control unit 276 may generate a synthesis screen in which the display color of the identifiably displayed geometric element is made the same as the display color of the synthetic element displayed in the synthetic element display area 712, and display the synthesis screen on the display unit 400.

In step SA15, the registration unit 274 registers a record in which the geometric element received in step SA12 is associated with the type of the logical operation received in step SA14 in the synthesis processing table as illustrated in FIG. 16. The synthesis processing table is configured such that a plurality of records can be registered. Each of the records includes one geometric element and a type of a logical operation of the one geometric element, and also includes, for example, information such as “Geometric element 1” and “Geometric element 2” as specific information for specifying the record. Furthermore, each of the records may include a preview parameter used at the time of previewing the geometric element, data indicating whether or not to execute the rounding process by the fraction processing unit 277, a resolution parameter in the case of executing the rounding process, a parameter after the rounding process by the fraction processing unit 277, and the like. For example, in a record of “Geometric element 1”, a geometric element is “Hexahedron”, a type of a logical operation is “+ (addition)”, and a parameter for previewing the hexahedron on the display unit 400 is associated with data indicating whether or not to execute the rounding process on the hexahedron, a resolution parameter at the time of performing the rounding process, and a parameter after the rounding process on the hexahedron by the fraction processing unit 277. Note that the preview parameter, the data indicating whether or not to execute the rounding process, the resolution parameter, and the parameter after the rounding process by the fraction processing unit 277 may be registered as necessary. Here, a case where the element rounding process is performed only on a geometric element that requires the element rounding process will be described. As described above, in each of the records included in the synthesis processing table, data indicating whether or not to execute the rounding process and a resolution in the case of executing the rounding process are registered for each of the records. For each of the records registered in the synthesis processing table, the fraction processing unit 277 determines whether or not to execute the rounding process on a coordinate value, a dimensional value, and an angular component of geometric element data based on data indicating whether or not to execute the rounding process associated with each of the records. The rounding process is executed on the geometric element data determined to be subjected to the rounding process based on a resolution parameter. Further, in a case where a resolution in the case of executing the rounding process is individually set for each of geometric elements on which the rounding process is to be executed, the fraction processing unit 277 acquires a resolution parameter associated with each of records for each of the records corresponding to the geometric elements on which the rounding process is to be executed, and performs fraction processing on at least one of the coordinate value, the dimensional value, and the angular component of the geometric element data based on the resolution parameter.

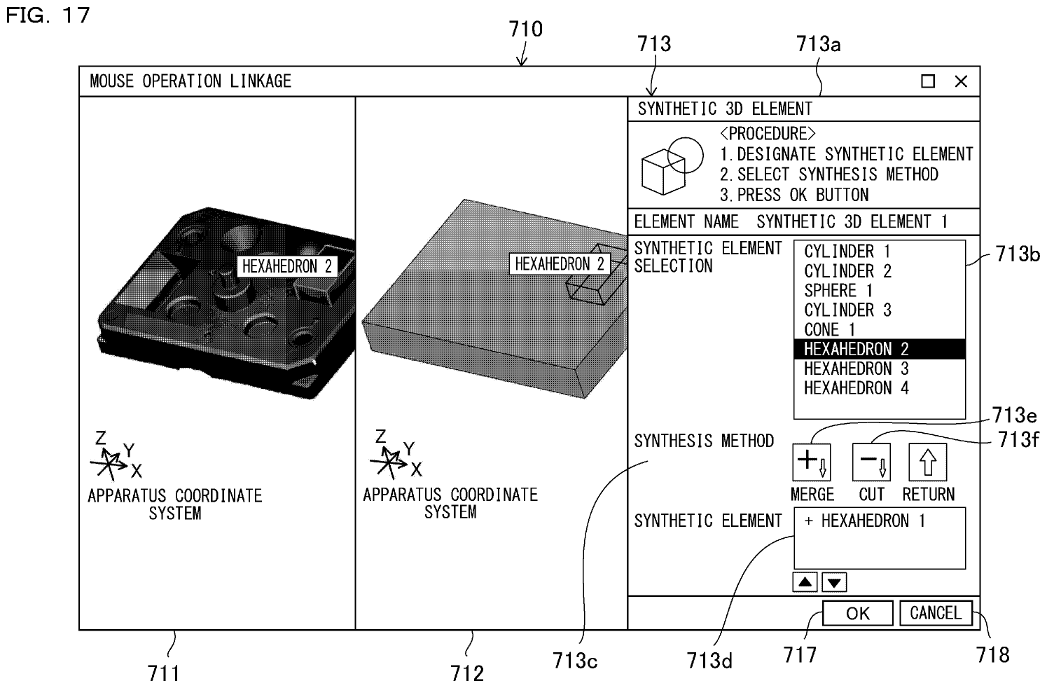

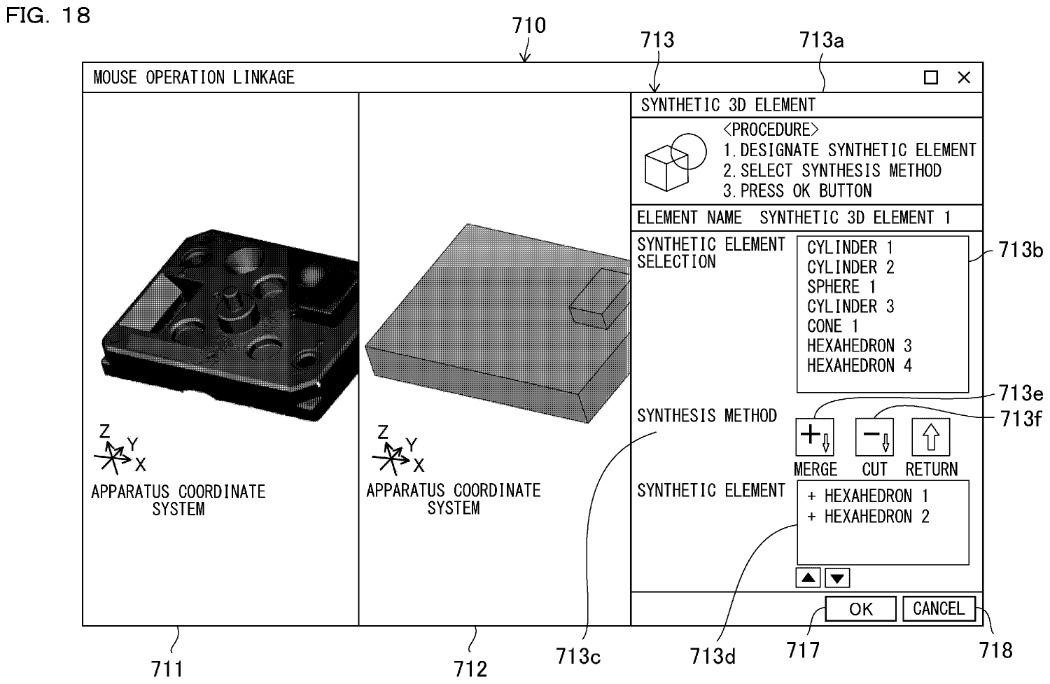

As illustrated in FIG. 17, the reception unit 273 can additionally receive selection of “Hexahedron 2” as a second geometric element. When the second geometric element is additionally received, the reception unit 273 can additionally receive selection of a type of a logical operation on the second geometric element as illustrated in FIG. 18. The registration unit 274 adds, to the synthesis processing table, a record in which the additionally received second geometric element is associated with the type of the logical operation on the second geometric element. Similarly, the reception unit 273 can additionally receive selection of a third geometric element and additionally receive selection of a type of a logical operation on the third geometric element, and the receivable number is not particularly limited.

As illustrated in FIG. 16, in the synthesis processing table, a plurality of records are arranged in order of reception by the reception unit 273. Specifically, a record located at the top of the synthesis processing table is a record received first by the reception unit 273, and records located second and third from the top are records received second and third, respectively. Further, a record located at the bottom of the synthesis processing table is a record received last by the reception unit 273. The arrangement order of the records in the synthesis processing table may be the synthesis order of geometric elements, and in this case, the computing unit 275 can synthesize geometric elements in the registration order of the records, that is, the arrangement order of the records. Although not illustrated, the records of the synthesis processing table may be arranged side by side, and in this case, the records can be arranged in order of reception.

In this manner, the synthesis processing table includes an item indicating the synthesis order of each geometric element, and a record registered in the synthesis processing table includes an index indicating the synthesis order of geometric elements included in the record. The computing unit 275 can acquire the index indicating the synthesis order of geometric elements included in the record. After acquiring the index indicating the synthesis order of the geometric elements included in the record, the computing unit 275 executes the logical operations on the plurality of records registered in the synthesis processing table based on the types of the logical operations associated with the records, respectively, and the index indicating the synthesis order, and creates a synthetic element. Note that the synthesis processing table may include an “operation group” that is an item indicating a group for grouping and computing a plurality of geometric elements, and further, an item indicating the synthesis order between operation groups or a type of a logical operation may be defined for each operation group. Specifically, it is assumed that Geometric element 1 and Geometric element 3 are Operation group a, and Geometric element 2 and Geometric element 4 are Operation group b. Further, it is assumed that these operation groups are synthesized in the order of Operation group a and Operation group b, and “addition” is designated as a type of a logical operation of each of Operation groups a and b. In this case, the computing unit 275 first computes Geometric element 1 and Geometric element 3 included in Operation group a based on the type of the logical operation associated with each record, and creates Intermediate synthetic element A. Next, the computing unit 275 operates Geometric element 2 and Geometric element 4 included in Operation group b based on the type of the logical operation associated with each record, and creates Intermediate synthetic element B. Then, Intermediate synthetic element A and Intermediate synthetic element B are synthesized based on the type of the logical operation associated with each of them to create Synthetic element AB. That is, the computing unit 275 may execute the logical operations on the geometric elements belonging to the same operation group based on information indicating the operation group included in the synthesis processing table to create an intermediate synthetic element, and then synthesize the intermediate synthetic elements based on information indicating the synthesis order between the operation groups to create the synthetic element.

In the selected element display area 713d, similarly to the synthesis processing table, geometric elements received by the reception unit 273 and types of logical operations respectively associated with the geometric elements can be arranged in order of reception. That is, in response to the reception unit 273 receiving selection of one geometric element displayed in the candidate display area 713 and selection of a type of a logical operation of the one geometric element from among types of a plurality of logical operations displayed in the type selection area 713c, the display control unit 276 adds the one geometric element to the selected element display area 713d to be displayed on the display unit 400. Since the synthesis order of geometric elements is illustrated in the selected element display area 713d in this manner, the user can easily grasp the synthesis order of the geometric elements by viewing the selected element display area 713d.

In step SA16 illustrated in FIG. 6, the computing unit 275 executes a logical operation in order from the top of the synthesis processing table. Specifically, in a case where a plurality of records are registered in the synthesis processing table, the computing unit 275 executes logical operations for the plurality of records registered in the synthesis processing table in the registration order of the records based on types of the logical operations included in the records, respectively, and creates a synthetic element. At this time, since the computing unit 275 executes the logical operations on the geometric elements based on geometric element data subjected to the fraction processing by the fraction processing unit 277, a computational process can be speeded up, and trial and error can be easily performed until CAD data is completed. Note that the case of executing the logical operations in the registration order of records has been described here, but information indicating the synthesis order may be associated with each of the records, and the logical operations may be executed based on the information indicating the synthesis order.

In step SA17, the synthetic element as a computation result in step SA16 is registered in the registration unit 274 and displayed on the display unit 400. For example, as illustrated in FIG. 18, in a case where “Hexahedron 1” is selected as the first geometric element with a type of “+” and “Hexahedron 2” is selected as the second geometric element with the type of “+”, a synthetic element including two “Hexahedron 1” and “Hexahedron 2” is created by the computing unit 275. The display control unit 276 displays the synthetic element computed by the computing unit 275 in the synthetic element display area 712. As a result, the user can confirm current data, and can determine whether or not there is a shortage of data, for example, whether there is no insufficient scan area such as a hole or a shadow.

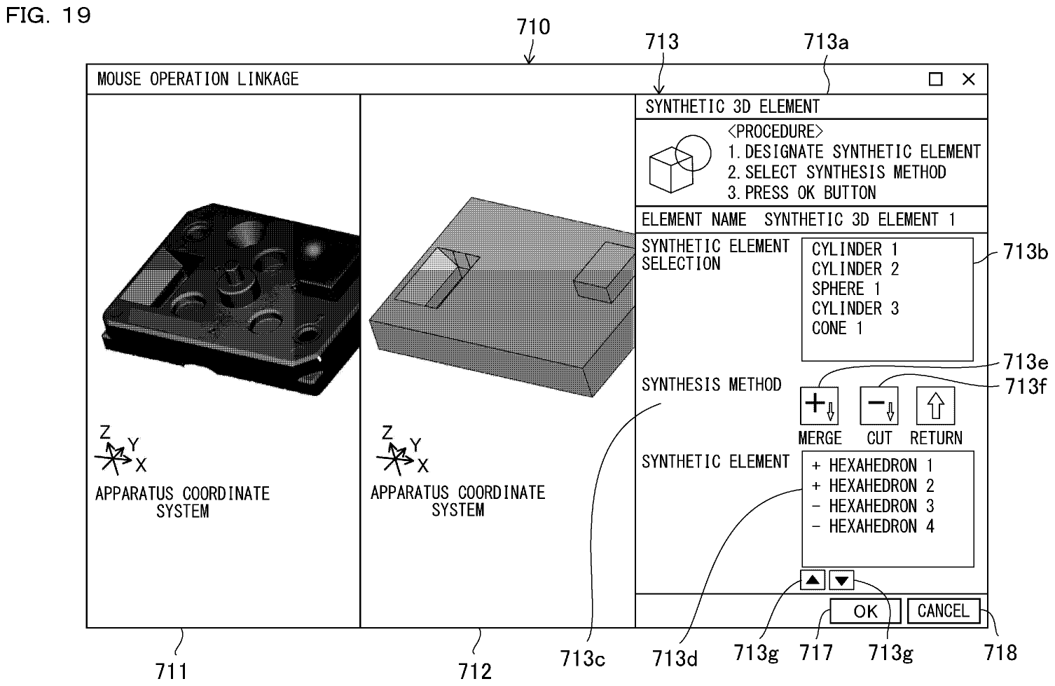

In step SA18, the reception unit 273 receives a determination as to whether synthesis is completed. In a case where the synthesis is not completed, the process proceeds to step SA12, and selection of another geometric element and selection of a type of a logical operation are received. For example, as illustrated in FIG. 19, in a case where “Hexahedron 3” is selected as a third geometric element with a type of “−” and “Hexahedron 4” is selected as a fourth geometric element with a type of “−”, a synthetic element obtained by subtracting “Hexahedron 3” and “Hexahedron 4” is created by the computing unit 275, and thus, a synthetic element is updated. The display control unit 276 displays the synthetic element updated by the computing unit 275 in the synthetic element display area 712.

When a plurality of geometric elements are displayed in the selected element display area 713d, the reception unit 273 is configured to be capable of receiving a change in the order of the plurality of geometric elements displayed in the selected element display area 713d. For example, when the operation button 713g displayed below the selected element display area 713d is operated to move a selected element displayed in the selected element display area 713d downward, the reception unit 273 lowers the order of the selected element. When the operation button 713g is operated to move the selected element displayed in the selected element display area 713d upward, the reception unit 273 raises the order of the selected element. In this manner, the user can switch or change the orders of any selected elements. Since the selected elements are associated with the types of the logical operations, respectively, the types of the logical operations are held even if the orders of the selected elements are switched.

When receiving the change in the order of the plurality of geometric elements by the reception unit 273, the computing unit 275 executes logical operations on the geometric elements displayed in the selected element display area 713d based on the types of the logical operations respectively associated with the geometric elements in the displayed order, and updates a synthetic element. Then, the display control unit 276 displays the synthetic element updated by the computing unit 275 on the display unit 400, and thus, the user can complete CAD data by trial and error while confirming the result of switching the orders of the geometric elements on the display unit 400.

The computing unit 275 can also compute a plurality of synthetic elements in parallel, instead of serially computing one synthetic element, and use the computed synthetic elements as inputs of a set operation. For example, in a case where the computing unit 275 computes a first intermediate synthetic element A obtained by computing a plurality of geometric elements belonging to Operation group a and a second intermediate synthetic element B obtained by computing a plurality of geometric elements belonging to Operation group b, different from the geometric elements constituting a first synthetic element, the computing unit 275 can compute a final synthetic element AB based on the first intermediate synthetic element A and the second intermediate synthetic element B using the first intermediate synthetic element A and the second intermediate synthetic element B as inputs of a set operation. For example, when the first synthetic element is set as an element of addition and a second synthetic element is set as an element of subtraction, it is also possible to reproduce a more intricate and complex shape.

Further, not only a three-dimensional geometric element but also a two-dimensional geometric element such as a plane can be used in the course of computing a synthetic element. Since a geometric element is extracted based on mesh data obtained by three-dimensional measurement, a part of the geometric element sometimes unnecessarily protrudes at the time of combination. In this case, an unnecessary shape can be easily deleted by using a two-dimensional geometric element such as a plane. For example, a two-dimensional geometric element can be arranged at a boundary between an unnecessary part and a necessary part of a three-dimensional geometric element, and a part located outside the two-dimensional geometric element can be deleted as the unnecessary part, or a part located inside the two-dimensional geometric element can be deleted as the unnecessary part.

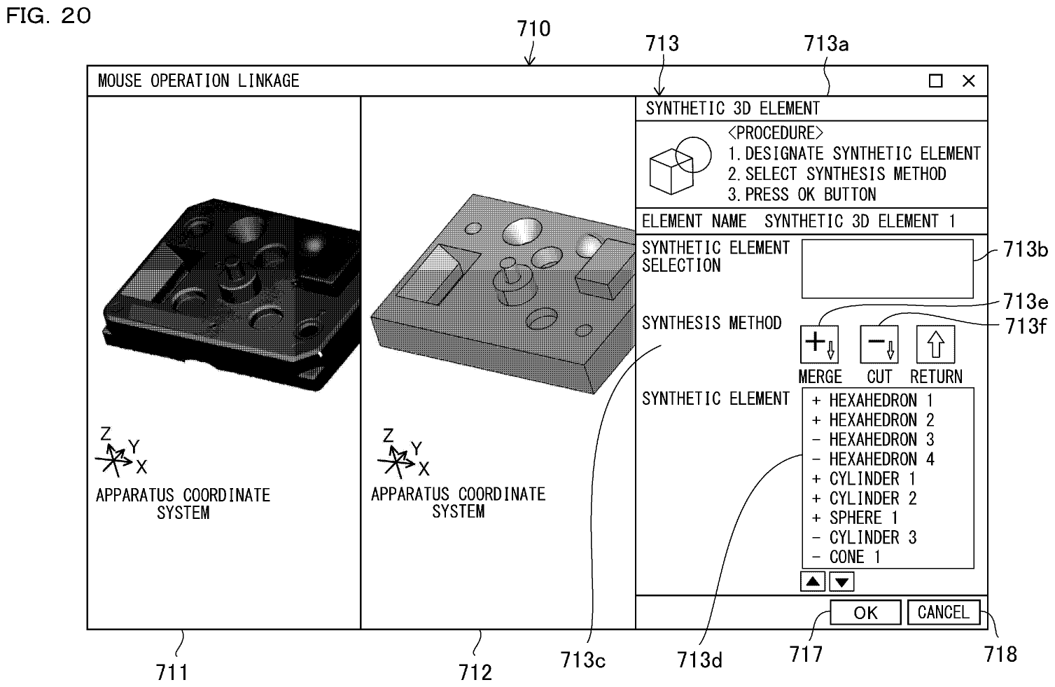

FIG. 20 illustrates completed CAD data. As illustrated in this drawing, when all the computations are completed, the process proceeds to step SA19, and the obtained CAD data is output to the outside.

### (Exception Determination Function)

As described above, when the computing unit 275 computes a synthetic element, a set operation of geometric elements is executed based on selected logical operation types, but an error may occur in the course of processing the set operation.

For example, a case where a geometric element associated with an operation type of “subtraction” or “multiplication” is designated at the head of the computation order is defined as an error case. In this case, the computing unit 275 always converts and adds the geometric element at the head of the computation order as an element of “addition”.

Further, a case where no valid solid area remains as a result of a set operation of a plurality of geometric elements is also regarded as an error case. The valid solid area is an area having a volume that can be converted into solid CAD data. When a computation of a synthetic element is completed, the computing unit 275 determines whether or not a valid solid area remains by converting output CAD a data into polygon. In a case where the polygon cannot be generated, the computing unit 275 determines that there is no valid solid area.

Further, an error due to a geometric element rounding process may also occur. When a geometric element is a sphere, a case where a radius of the sphere becomes 0 as a result of rounding a dimensional value of the sphere is regarded as an error case. Further, when a geometric element is a rectangular parallelepiped, a case where two opposing faces completely match as a result of rounding a dimensional value of the rectangular parallelepiped is regarded as an error case. Furthermore, when a geometric element is a truncated cone, a case where a cylinder is obtained as a result of rounding a dimensional value of a conical body is regarded as an error case.

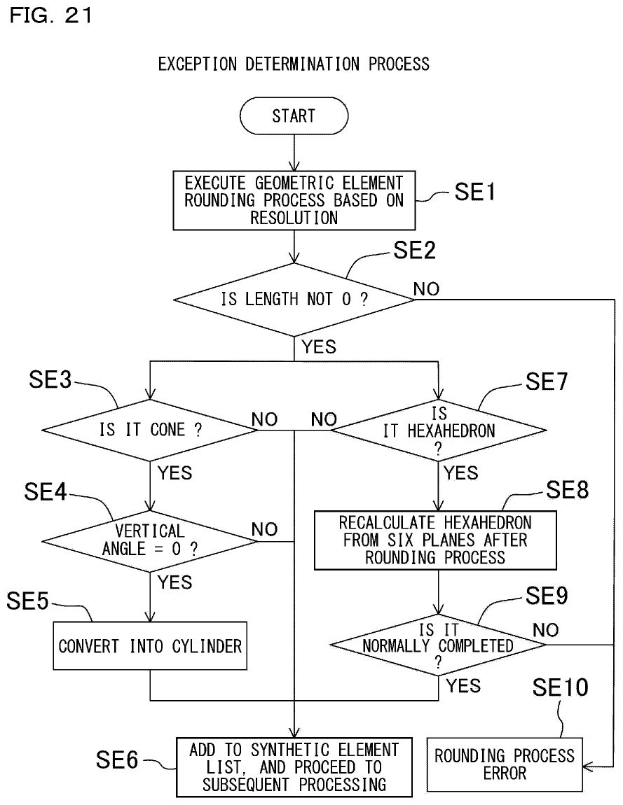

FIG. 21 is a flowchart illustrating an example of an exception determination process. In step SE1, the fraction processing unit 277 executes a rounding process on a geometric element based on the resolution parameter input in step SA8 of FIG. 6. In step SE2, the computing unit 275 determines whether a value is 0 as a result of the rounding process by the fraction processing unit 277. In a case where the value is 0, the process proceeds to step SE3 to determine whether or not the geometric element is a cone. In the case of the cone, the process proceeds to step SE4 to determine whether or not a vertical angle is 0. In a case where the vertical angle is 0, conversion into a cylinder is performed, and the process proceeds to step SE6 to add the geometric element to the synthetic element selection area 713b.

When proceeding from step SE2 to step SE7, it is determined whether the geometric element is a hexahedron. In the case of the hexahedron, the process proceeds to step SE8, and the computing unit 275 recalculates a hexahedron from six planes after having been subjected to the rounding process. In step SE9, it is determined whether the calculation in step SE8 is normally completed. In a case where the recalculation of the hexahedron is normally completed, the process proceeds to step SE6, and the geometric element is added to the synthetic element selection area 713b. On the other hand, in a case where it is determined as NO in step SE2 and a length becomes 0, and in a case where the recalculation of the hexahedron is not normally completed in step SE9, the process proceeds to step SE10, and it is determined that an error occurs in the rounding process. In this manner, when the error occurs in the rounding process, such a determination result is displayed on the list of the synthetic element selection area 713b. When creation of a synthetic element is to be completed in a state in which the geometric element for which the error occurs in the rounding process is added to the list of the synthetic element selection area 713b, the error is notified to the user.

### (Recalculation Process)

There is a case where a defect is present in mesh data itself of the workpiece W measured by the scanner module 260. In the reverse engineering support apparatus 1 according to the present embodiment, the mesh data can be added by three-dimensional measurement while holding an extracted geometric element and a set operation method thereof even in the case where the defect is present in the mesh data itself.

Further, there is a case where mesh data is edited in filling processing, unnecessary portion removal processing, healing processing, remeshing processing, and the like during a reverse engineering process. For example, the filling processing is processing of specifying open edges (edges having no adjacent polygon) on the mesh data, specifying a loop including continuous open edges, and then, creating new mesh data in the loop to correct the loop. Further, the remeshing processing is processing of bringing a triangle of the mesh close to an equilateral triangle. In a case where the mesh data is edited as described above, the reverse engineering support apparatus 1 according to the present embodiment can re-extract a geometric element for the edited mesh data and automatically recalculate a result of a set operation.

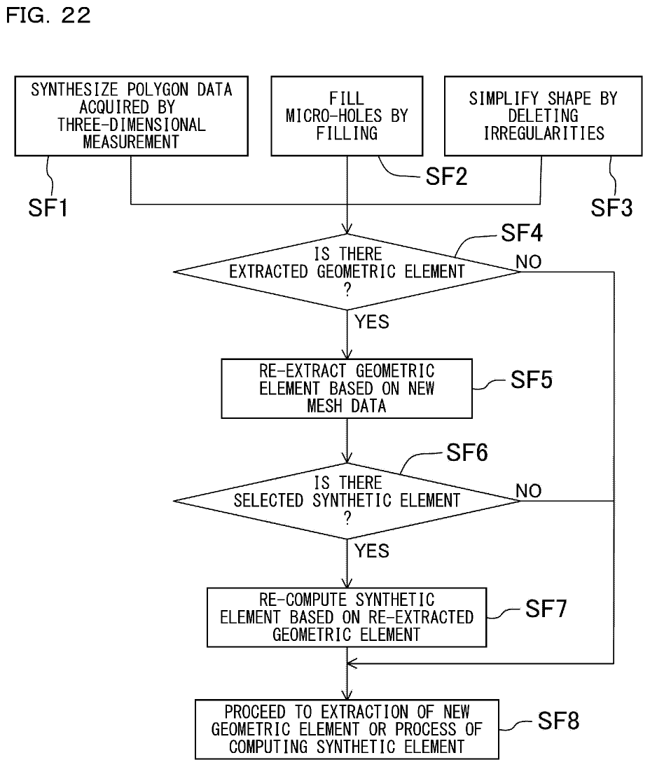

A recalculation process will be specifically described based on a flowchart illustrated in FIG. 22. At the start, mesh data acquired by three-dimensional measurement in step SF1 is synthesized, micro holes are closed by filling processing in step SF2, and a shape is simplified by deleting irregularities in step SF3.

In step SF4, it is determined whether there is an extracted geometric element. In a case where there is an extracted geometric elements, a geometric element is re-extracted based on new mesh data in step SF5. In step SF6, it is determined whether there is a selected synthetic element. In a case where there is a selected synthetic element, a synthetic element is re-computed based on the re-extracted geometric element in step SF7. In step SF8, the process proceeds to new extraction of a geometric element and the process of computing a synthetic element. On the other hand, in a case where it is determined as NO in step SF4 and there is no extracted geometric element, and in a case where it is determined as NO in step SF6 and there is no selected synthetic element, the process directly proceeds to step SF8. Through the above processes, it is possible to create solid CAD data corresponding to the workpiece W as a real object while compensating for a defective site.

The above-described embodiment is merely an example in all respects, and should not be construed as limiting. Further, all modifications and changes belonging to the equivalent range of the claims fall within the scope of the invention.

As described above, the reverse engineering support apparatus according to the disclosure can be used, for example, in a case where a shape of a real object is acquired and converted into design data.

What is claimed is:

1. A reverse engineering support apparatus that converts mesh data, obtained by measuring a shape of a workpiece, into CAD data and outputs the CAD data, the reverse engineering support apparatus comprising:
a data acquisition unit that acquires the mesh data of the workpiece;
an extraction unit that extracts a plurality of geometric elements from the mesh data of the workpiece acquired by the data acquisition unit;
a reception unit that receives selection of one geometric element from among the plurality of geometric elements extracted by the extraction unit and receives selection of a type of a logical operation of the one geometric element;
a registration unit configured to be capable of registering, in a synthesis processing table, a plurality of records in which types of logical operations received by the reception unit are associated with geometric elements received by the reception unit, respectively;
a computing unit that executes a logical operation of a geometric element based on a type of the logical operation associated with each of the records for each of the records, included in the synthesis processing table and registered by the registration unit, to create a synthetic element; and
a display control unit that causes a display unit to display the synthetic element created by the computing unit.

2. The reverse engineering support apparatus according to claim 1, wherein
the reception unit additionally receives selection of one geometric element and selection of a type of a logical operation of the one geometric element,
the registration unit adds, to the synthesis processing table, a record in which the one additionally received geometric element is associated with the type of the logical operation of the one geometric element,
the computing unit executes the logical operation of the one geometric element and the synthetic element based on the record added to the synthesis processing table to update the synthetic element, and
the display control unit causes the display unit to display the synthetic element updated by the computing unit.

3. The reverse engineering support apparatus according to claim 1, wherein
the display control unit causes the display unit to display a synthesis screen including
a mesh display area in which the mesh data acquired by the data acquisition unit is displayed,
a synthetic element display area in which the synthetic element computed by the computing unit is displayed, and
a candidate display area in which the plurality of geometric elements extracted by the extraction unit are displayed as synthesis candidates, and
the reception unit receives selection of one geometric element to be used for a logical operation from among the plurality of geometric elements displayed in the candidate display area.

4. The reverse engineering support apparatus according to claim 1, wherein
the computing unit executes the logical operations for the plurality of records registered in the synthesis processing table based on the types of the logical operations included in the records, respectively, in order of registration of the records to create the synthetic element.

5. The reverse engineering support apparatus according to claim 1, wherein
the synthesis processing table includes items indicating synthesis orders of the geometric elements, respectively, and the records respectively include indices indicating the synthesis orders of the geometric elements included in the records,
the computing unit executes the logical operations on the plurality of records registered in the synthesis processing table based on the types of the logical operations and the indices indicating the synthesis orders associated with the records, respectively, to create the synthetic element.

6. The reverse engineering support apparatus according to claim 3, wherein
the synthesis screen further includes a type selection area for selecting a logical operation type, and
the type selection area is provided with an icon for designating a logical operation type of one geometric element received by the reception unit.

7. The reverse engineering support apparatus according to claim 6, wherein
display of a selected element display area in which a synthesis order of the synthetic element is displayed is possible, and
the display control unit adds one geometric element to the selected element display area to be displayed on the display unit in response to reception, by the reception unit, of selection of the one geometric element displayed in the candidate display area and selection of a type of a logical operation of the one geometric element from among a plurality of logical operation types displayed in the type selection area.

8. The reverse engineering support apparatus according to claim 7, wherein
the reception unit is configured to be capable of receiving a change in order of a plurality of geometric elements displayed in the selected element display area,
when the reception unit receives the change in the order of the plurality of geometric elements, the computing unit executes logical operations of the geometric elements displayed in the selected element display area based on types of the logical operations associated with the geometric elements, respectively, in the displayed order to update the synthetic element, and
the display control unit causes the display unit to display the synthetic element updated by the computing unit.

9. The reverse engineering support apparatus according to claim 3, wherein
the display control unit causes the display unit to display the synthesis screen in which one geometric element is superimposed on each of the mesh display area and the synthetic element display area in response to selection of the one geometric element from the candidate display area.

10. The reverse engineering support apparatus according to claim 9, wherein
the display control unit causes the display unit to display the synthesis screen in which the one geometric element is identifiably displayed by making a display color of the one geometric element different from a display color of the mesh data displayed in the mesh display area.

11. The reverse engineering support apparatus according to claim 9, wherein
the display control unit causes the display unit to display the synthesis screen in which the one geometric element is identifiably displayed by making a display color of the one geometric element different from a display color of the synthetic element displayed in the synthetic element display area.

12. The reverse engineering support apparatus according to claim 11, wherein
when a logical operation of the identifiably displayed geometric element is executed by the computing unit, the display control unit causes the display unit to display the synthesis screen in which a display color of the geometric element that has been identifiably displayed is made identical to the display color of the synthetic element displayed in the synthetic element display area.

13. The reverse engineering support apparatus according to claim 3, wherein
the reception unit is configured to be capable of additionally receiving selection of a geometric element displayed on the synthesis screen and selection of a type of a logical operation of the one geometric element.

14. The reverse engineering support apparatus according to claim 13, wherein
the synthesis screen further includes a geometric element extraction screen for extracting a geometric element by the extraction unit.

15. The reverse engineering support apparatus according to claim 14, wherein
the synthesis screen further includes an icon for transitioning to the geometric element extraction screen.

16. The reverse engineering support apparatus according to claim 1, further comprising
a fraction processing unit that executes fraction processing on at least one of a coordinate value and a dimensional value of geometric element data extracted by the extraction unit,
wherein the computing unit executes a logical operation of a geometric element based on the geometric element data subjected to the fraction processing by the fraction processing unit.

17. The reverse engineering support apparatus according to claim 16, wherein
the registration unit is configured to be capable of registering data indicating necessity of the fraction processing for each of the records in the synthesis processing table, and
the fraction processing unit determines whether or not to execute the fraction processing on at least one of the coordinate value and the dimensional value of the geometric element data based on the data indicating the necessity of the fraction processing associated with each of the records for each of the records registered in the synthesis processing table.

18. The reverse engineering support apparatus according to claim 17, wherein
the registration unit is configured to be capable of registering a resolution parameter of the fraction processing in the synthesis processing table for each of the records, and
the fraction processing unit acquires the resolution parameter associated with each of records for the records respectively corresponding to geometric elements for which the fraction processing is to be executed, and executes the fraction processing on at least one of the coordinate value and the dimensional value of the geometric element data based on the acquired resolution parameter.
